(19) United States
(12) Patent Application Publication
(10) Pub. No.: US 2013/0051158 A1
(43) Pub. Date: Feb. 28, 2013

(54) INTEGRATED CIRCUIT, TESTING APPARATUS FOR INTEGRATED CIRCUIT, AND METHOD OF TESTING INTEGRATED CIRCUIT

(71) Applicant: Tatsuru MATSUO, Kawasaki (JP)

(72) Inventor: Tatsuru MATSUO, Kawasaki (JP)

(73) Assignee: FUJITSU LIMITED, Kawasaki-shi (JP)

(21) Appl. No.: 13/534,448

(22) Filed: Jun. 27, 2012

(30) Foreign Application Priority Data
Aug. 24, 2011 (JP) 2011-182628

(51) Int. Cl. G11C 29/36

(52) U.S. Cl. 365/189.07

(57) ABSTRACT

Provided are a redundant memory; a generator that generates a test pattern, and an expected value of data expected to be output from the redundant memory, in response to the test pattern being supplied to the redundant memory; a comparator that compares the expected value generated by the generator, against data output from the redundant memory in response to the test pattern being supplied to the redundant memory; a storage that stores a result of the comparison by the comparator; and a write controller that writes the comparison result to the storage while relating the comparison result to location information in the redundant memory where the comparison result is produced, if the comparison result by the comparator indicates a mismatch, while suppressing the comparison result from being written to the storage, if the comparison result by the comparator indicates a match.

### CROSS-REFERENCE TO RELATED APPLICATION

This application is based upon and claims the benefit of priority of the prior Japanese Application No. 2011-182628 filed on Aug. 24, 2011 in Japan, the entire contents of which are hereby incorporated by reference.

### FIELD

The present disclosure relates to an integrated circuit, a testing apparatus for an integrated circuit, and a method of testing an integrated circuit.

### BACKGROUND

After manufacturing integrated circuits, such as large scale integrated circuits (LSIs), memories on the manufactured LSIs are tested in a test for detecting any defect in the LSIs. Memories on an LSI are tested using a memory built-in self test (BIST) circuit added to the LSI. A memory BIST circuit is configured as depicted in FIG. 20, for example. FIG. 20 is a block diagram illustrating a configuration of an LSI 100 including a typical memory BIST circuit 110.

As depicted in FIG. 20, the LSI 100 includes a memory 101 to be tested and the memory BIST circuit 110. Here, the memory 101 is a non-redundant memory, without a spare memory cell. The memory BIST circuit 110 includes a test signal generation circuit 111, the compare circuit 112, and comparison result storage circuit 113.

The test signal generation circuit 111 generates a test pattern, an expected value ERD, and a store instruction SEN.

The test pattern is an input signal to be supplied to the memory 101 to be tested, and particularly includes a read/write instruction RW, an address ADR, and write data WD.

The expected value ERD is a value of data that is expected to be output from the memory 101 in response to the test pattern being supplied to the memory 101. The expected value ERD is supplied to the compare circuit 112.

The store instruction SEN is a signal for instructing the timing when a result of comparison by the compare circuit 112 (comparison result) is to be stored into the comparison result storage circuit 113.

The compare circuit 112 compares the expected value ERD generated by the test signal generation circuit 111, against the data (i.e., the read data RD) output from the memory 101 in response to the test pattern being supplied to the memory 101. The compare circuit 112 outputs, as a comparison result CMP, a value “0”, for example, if the expected value ERD matches the read data RD, and outputs a value “1”, for example, if they do not match. During a test of the memory 101, multiple test patterns are generated, and the compare circuit 112 makes comparisons for the respective test patterns.

The comparison result storage circuit 113 stores a comparison result CMP from the compare circuit 112, in response to a store instruction SEN from the test signal generation circuit 111. More specifically, the comparison result storage circuit 113 stores a value indicating whether or not a mismatch is found in at least one of the multiple comparison results obtained by the compare circuit 112. For example, the comparison result storage circuit 113 stores the value “1” when a mismatch is found in at least one of the multiple comparison results obtained by the compare circuit 112, while storing the value “0” if no mismatch is found, as a comparison result.

Note that the comparison result storage circuit 113 does not have to capture the comparison result CMP from the compare circuit 112, and it actually stores the comparison result CMP from the compare circuit 112 at rising of the store instruction SEN from the test signal generation circuit 111. That is, the compare circuit 112 makes a comparison, in a cycle next to the cycle when read data RD is read from the memory 101, in response to a read instruction. Accordingly, the test signal generation circuit 111 generates the store instruction SEN such that the comparison result CMP from the compare circuit 112 is captured by the comparison result storage circuit 113 in the next cycle.

In FIG. 20, “a” denotes the address count, and the “b” denotes the bit count.

Next, the procedure for testing the memory 101 using the above-described memory BIST circuit 110 will be described.

Upon testing the memory 101 using the memory BIST circuit 110, firstly, an LSI tester 200 is connected to the LSI 100. More specifically, the LSI tester 200 is connected to the test signal generation circuit 111 and the comparison result storage circuit 113 on the LSI 100, through a scan path 300. The LSI tester 200 is also connected to clock terminals of the test signal generation circuit 111, the memory 101 and the comparison result storage circuit 113, through a clock signal line 301.

While the LSI 100 is connected to the LSI tester 200, the LSI tester 200 initializes the memory BIST circuit 110 by supplying data through the scan path 300, and supplying a clock CLK through the clock signal line 301.

After the initialization, the clock CLK is supplied, and the memory 101 is tested by the test signal generation circuit 111 by suitably generating a test pattern, an expected value ERD, and a store instruction SEN, in the LSI 100. The comparison result CMP from the compare circuit 112 is then stored in the comparison result storage circuit 113.

After the test of the memory 101, the LSI tester 200 supplies a clock CLK through the clock signal line 301, and reads the comparison result in the comparison result storage circuit 113 through the scan path 300. The LSI tester 200 determines the examined LSI 100 as defective if “at least one mismatch is found” in the comparison results that are read, while determining the examined LSI 100 as non-defective if “no mismatch is found” in the comparison results that are read.

In FIG. 20, the examined memory is a non-redundant memory. An example where an examined memory is a redundant memory having spare memory cells will be described below with reference to FIG. 21. FIG. 21 is a block diagram illustrating a functional configuration of an LSI 100A including a redundant memory 101A as a memory to be tested.

As depicted in FIG. 21, the LSI 100A includes a redundant memory 101A to be tested, a memory BIST circuit 110, a defect location information obtainment circuit 120, and a FUSE 130.

Here, the memory BIST circuit 110 is similar to that depicted in FIG. 20, and the description therefor will be omitted.

The defect location information obtainment circuit 120, if a defect arises during a test of the redundant memory 101A by the memory BIST circuit 110, that is, the comparison result from the compare circuit 112 indicates a mismatch, information (e.g., an address) that can identify a failed location where the defect (mismatch) arises in the redundant memory 101A, is obtained as defect location information.

The FUSE (non-volatile storage device) 130 replaces the memory cell in the failed location where the defect arises, based on defect location information obtained by the defect location information obtainment circuit 120, with a spare memory cell. The FUSE 130 can retain information even after power-down and can be switched by means of a physical or electric operation within the LSI to replace the memory cell in the failed location with the spare memory cell.

Next, a procedure for a test and repair of the redundant memory 101A depicted in FIG. 21 will be described.

Firstly, a test of a redundant memory 101A is performed using the memory BIST circuit 110. The procedure for testing the redundant memory 101A is similar to the test procedure for the non-redundant memory 101 noted above, and the description thereof will be omitted. During the test of the redundant memory 101A, however, a failed location (e.g., the address) in the redundant memory 101A where the defect arises is obtained as defect location information by the defect location information obtainment circuit 120.

If no defect location information is obtained for the redundant memory 101A, the redundant memory 101A is used without any repair. If defect location information is obtained for the redundant memory 101A, repair information is generated from the defect location information by a dedicated circuit inside the LSI tester 200 or the LSI 100A, and the resultant repair information is written to a FUSE 130 connected to the redundant memory 101A. Once the repair information is written to the FUSE 130, the memory cell in the failed location is replaced with a spare memory cell.

A defect location information obtainment circuit 120 typically includes a dedicated flip flop (FF) for storing defect location information. This may present a problem of an increased circuit size of the defect location information obtainment circuit 120, if the size of obtained defect location information is significant.

To address this issue, in Patent Literature 1 (Japanese Laid-open Patent Publication 2001-14890), location information is not stored in a dedicated FF, but in a memory provided in an LSI.

Here, a configuration and problems of Patent Literature 1 will be discussed. In the configuration of Patent Literature 1, two banks A and B, having the same size and addresses corresponding to each other one-to-one, are provided on an LSI, as redundant memories.

Upon a test, defect location information of the bank B is obtained first. Here, the defect location information is then stored in an external LSI tester. Then, the memory cell in the failed location in the bank B is replaced with a spare memory cell, based on defect location information stored in that LSI tester.

After assuring that the bank B has no defect by repairing the bank B in this manner and, a test and repair of the bank A is performed using the bank B. More specifically, data read from each address in the bank A is compared against an expected value, and the result of the comparison (a match or mismatch, i.e., normal or defect information, for each address) is produced using a memory BIST circuit. The comparison result obtained for each address in the bank A is written to the same address in the bank B. Thereby, the comparison result of the bank A are written to the bank B, while being related to location information (address) where the comparison result is produced in the bank A.

The address where the defect information is written is then obtained as defect location information of the bank A, by referencing to the comparison result in each address in the bank B, and the memory cell in the failed location in the bank A is replaced with a spare memory cell, based on the defect location information.

Upon testing a memory, a defect evaluation memory test pattern (which will be described later with reference to FIG. 19) is used. The defect evaluation memory test pattern is used for comparing addresses in the examined memory (bank A) in multiple times, to obtain multiple comparison results. If a defect arises in a memory cell at a certain address, all of the comparison results obtained in the multiple comparison results may indicate mismatches, or a part of the comparison results may indicate mismatches while others indicate matches.

Accordingly, when a comparison result for each address in the bank A is written to the same address in the bank B, a new comparison result is overwritten to an old comparison result if the previous comparison result has been already written to that address in the bank B. Hence, when a part of the comparison results may indicate mismatches while others indicate matches as described above, if the comparison result that is overwritten the last in the address in the bank B indicates a match, the old comparison result indicating a mismatch is erased and defect location information in the bank A becomes unavailable any more. As a result, the memory cell in the failed location cannot be identified, which is a redundant memory in the bank A, and the bank A cannot be repaired by replacing the memory cell in the failed location, with a spare memory cell.

When testing and repairing the bank B before the bank A, the defect location information of the bank B cannot be stored other destinations than the LSI tester which is outside the LSI. In such a case, the LSI tester cannot store the defect location information at a frequency higher than the operating frequency of the LSI tester. If the internal clock rate of the LSI exceeds the operating frequency of the LSI tester, defect location information cannot be stored in the LSI tester and accordingly the defect location information becomes unavailable. Stating differently, some LSI testers cannot handle memory tests at higher clock frequencies, and such LSI testers cannot find memory defects appearing only at higher clock rates.

### SUMMARY

An integrated circuit of the present disclosure include a redundant memory comprising a spare memory cell, a first generator, a first comparator, at least one storage, and a write controller. The first generator generates a first test pattern to be provided to the redundant memory, and an expected value of data expected to be output from the redundant memory, in response to the first test pattern being supplied to the redundant memory. The first comparator compares the expected value generated by the first generator, against data output from the redundant memory in response to the first test pattern generated by the first generator being supplied to the redundant memory. The at least one storage stores a result of the comparison by the first comparator. The write controller writes the comparison result to the at least one storage while relating the comparison result to location information in the redundant memory where the comparison result is produced, if the comparison result by the first comparator indicates a mismatch, while suppressing the comparison result from being written to the at least one storage, if the comparison result by the first comparator indicates a match.

Further, a testing apparatus of the present disclosure is a testing apparatus provided in an integrated circuit and testing memories in the integrated circuit, wherein the testing apparatus includes the first generator, the first comparator, the at least one storage, and the write controller, as described above, for testing a redundant memory including a spare memory cell.

Further, a method of testing an integrated circuit of the present disclosure is a method of testing an integrated circuit including the redundant memory, the first generator, the first comparator, the at least one storage, and the write controller, as described above, wherein the method includes initializing by writing an initial value to respective memory cells in the at least one storage; if the comparison result by the first comparator indicates a mismatch, writing the comparison result to the at least one storage while relating the comparison result to the location information in the redundant memory where the comparison result is produced, by writing a value different from the initial value, as the comparison result, in a location in the at least one storage corresponding to a location in the redundant memory where the comparison result is produced; and suppressing the comparison result from being written to the at least one storage, if the comparison result by the first comparator indicates a match.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a block diagram illustrating a configuration of an integrated circuit including a testing apparatus in a first embodiment;

FIG. 2 is a block diagram illustrating a detailed configuration of a defect location information obtainment circuit in the integrated circuit depicted in FIG. 1;

FIG. 3 is a block diagram illustrating a detailed configuration of the integrated circuit depicted in FIGS. 1 and 2;

FIG. 4 is a flowchart illustrating a memory test procedure in an integrated circuit depicted in FIGS. 1 to 3;

FIG. 5 is a block diagram illustrating a configuration of an integrated circuit including a testing apparatus in a second embodiment;

FIG. 6 is a block diagram illustrating a detailed configuration of a defect location information obtainment circuit in the integrated circuit depicted in FIG. 5;

FIG. 7 is a block diagram illustrating a configuration of an integrated circuit including a testing apparatus in a third embodiment;

FIG. 8 is a block diagram illustrating a detailed configuration of a defect location information obtainment circuit in the integrated circuit depicted in FIG. 7;

FIG. 9 is a block diagram illustrating a configuration of an integrated circuit including a testing apparatus of a fourth embodiment;

FIG. 10 is a block diagram illustrating a detailed configuration of a defect location information obtainment circuit in the integrated circuit depicted in FIG. 9;

FIG. 11 is a flowchart illustrating a memory test procedure in the integrated circuit depicted in FIGS. 9 and 10;

FIG. 12 is a block diagram illustrating a configuration of an integrated circuit including a testing apparatus of a fifth embodiment;

FIG. 13 is a block diagram illustrating a detailed configuration of a defect location information obtainment circuit in the integrated circuit depicted in FIG. 12;

FIG. 14 is a block diagram illustrating a configuration of an integrated circuit including a testing apparatus of a sixth embodiment;

FIG. 15 is a block diagram illustrating a detailed configuration of a defect location information obtainment circuit in the integrated circuit depicted in FIG. 14;

FIGS. 16A to 16C depict circuit configurations of redundant memories, wherein FIG. 16A is a diagram illustrating a circuit configuration of a row redundancy type redundant memory, FIG. 16B is a diagram illustrating a circuit configuration of a column redundancy type redundant memory, and FIG. 16C is a diagram illustrating a circuit configuration of a row+column redundancy type redundant memory;

FIG. 17 is a block diagram illustrating a configuration of an LSI wherein both redundant memories and non-redundant memories are present;

FIG. 18 is a flowchart illustrating a typical memory test procedure for an LSI wherein both redundant memories and non-redundant memories are present;

FIG. 19 is a flowchart illustrating an example of a typical defect evaluation memory test pattern;

FIG. 20 is a block diagram illustrating a configuration of an LSI including a typical memory BIST circuit; and

FIG. 21 is a block diagram illustrating a configuration of an LSI including a redundant memory as a memory to be tested.

### DESCRIPTION OF THE PREFERRED EMBODIMENTS

Hereunder is a description of embodiments with reference to the drawings.

### (1) REDUNDANT MEMORIES

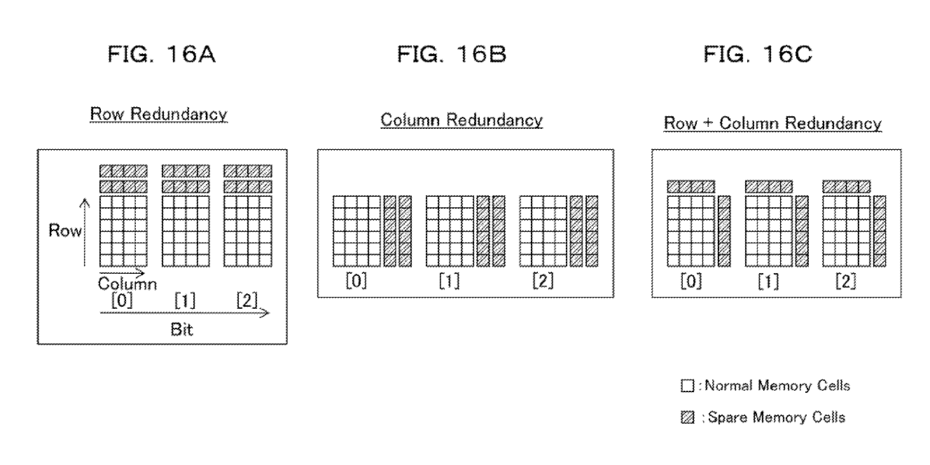

Now referring to FIGS. 16A to 16C, a configuration of redundant memories to be tested and/or repaired in present embodiments will be described in detail. FIGS. 16A to 16C depict circuit configurations of redundant memories, wherein FIG. 16A is a diagram illustrating a circuit configuration of a row redundancy type redundant memory, FIG. 16B is a diagram illustrating a circuit configuration of a column redundancy type redundant memory, and FIG. 16C is a diagram illustrating a circuit configuration of a row+column redundancy type redundant memory;

A redundant memory includes spare memory cells, in addition to normal memory cells. The particular circuit configurations of redundant memories vary, depending on the arrangements of spare memory cells and units for replacing the spare memory cells.

As depicted in FIG. 16A, a row redundant type redundant memory includes, for each bit, m*n (7*4, in the drawing) memory cells corresponding to addresses and spare memory cells in a plurality of row unit sets (four in two sets, in the drawing). In such a row redundant type redundant memory, the row address of a memory cell where a defect arises is obtained as defect location information. If a memory cell defect arises, the memory cells where the defect arises are replaced with spare memory cells, on a row-by-row basis. Note in the example depicted in FIG. 16A, if memory cell defects arise in three or more different rows, it is determined that the defects cannot be repaired since there is no spare memory cells sufficient for repair.

As depicted in FIG. 16B, a column redundant type redundant memory includes, for each bit, m*n (7*4, in the drawing) memory cells corresponding to addresses and spare memory cells in a plurality of column unit sets (seven in two sets, in the drawing). In such a column redundant type redundant memory, the column address of a memory cell where a defect arises is obtained as defect location information. If a memory cell defect arises, the memory cells where the defect arises are replaced with spare memory cells, on a column-by-column basis. Note in the example depicted in FIG. 16B, if memory cell defects arise in three or more different columns, it is determined that the defects cannot be repaired since there is no spare memory cells sufficient for repair.

As depicted in FIG. 16C, a row+column redundant type redundant memory includes, for each bit, m*n (7*4, in the drawing) memory cells corresponding to addresses, spare memory cells in one or more row unit sets (four in one set, in the drawing), spare memory cells in one or more column unit sets (seven in one set, in the drawing). In such a row+column redundant type redundant memory, the address (row address+column address) of a memory cell where a defect arises is obtained as defect location information. If a memory cell defect arises, the memory cells where the defect arises are replaced with spare memory cells, on a row-by-row or column-by-column basis. Note in the example depicted in FIG. 16B, if memory cell defects arise in three or more different cell rows or cell columns, it is determined that the defects cannot be repaired since there is no spare memory cells sufficient for repair.

### (2) TYPICAL MEMORY TESTING PROCEDURE FOR REDUNDANT MEMORIES AND NON-REDUNDANT MEMORIES

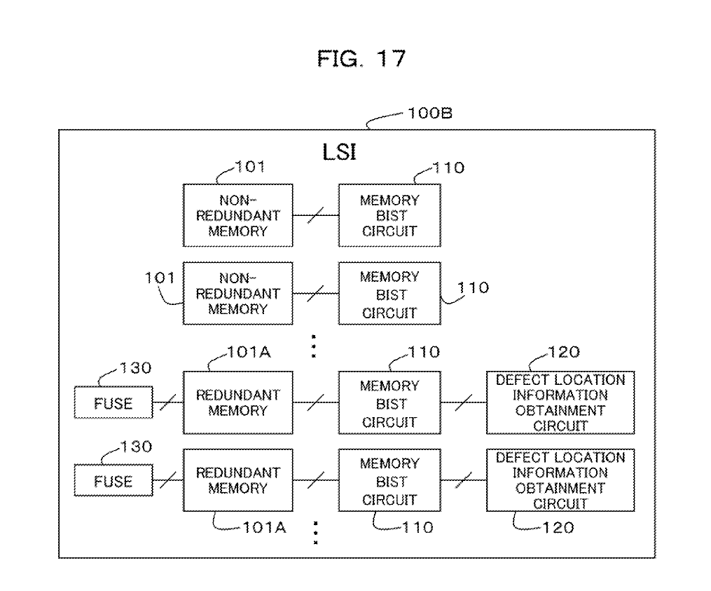

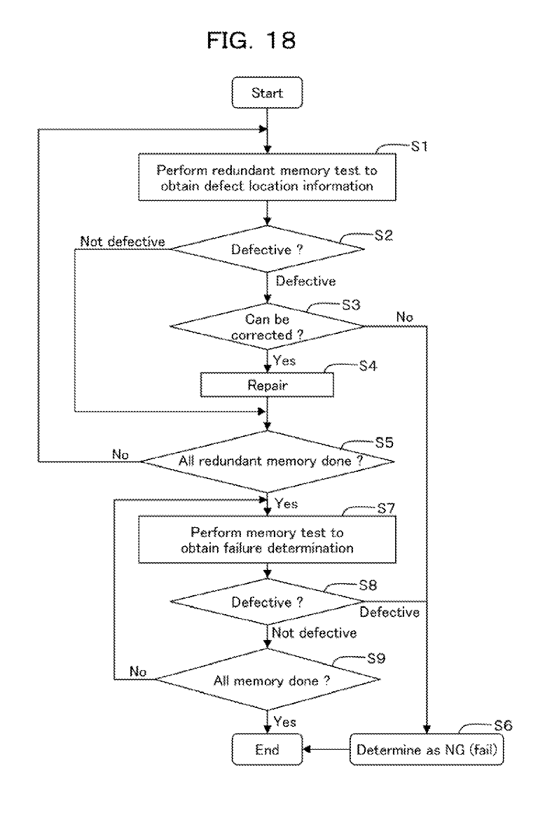

Now, referring to FIGS. 17 and 18, a memory test procedure for a typical LSI wherein both redundant memories and non-redundant memories are present, will be described. FIG. 17 is a block diagram illustrating a configuration of an LSI wherein both redundant memories and non-redundant memories are present, and FIG. 18 is a flowchart illustrating a typical memory test procedure for an LSI wherein both redundant memories and non-redundant memories are present.

As depicted in FIG. 17, the typical the LSI 100B includes multiple memories, including non-redundant memories 101 and redundant memories 101A. In such an LSI 100B wherein both the redundant memories 101 and the non-redundant memories 101A are present, a memory BIST circuit 110 is provided for each non-redundant memory 101, and a memory BIST circuit 110, a defect location information obtainment circuit 120, and a FUSE 130 are provided for each redundant memory 101A.

A typical test procedure for the non-redundant memories 101 and the redundant memories 101A in the LSI 100B will be described with reference to the flowchart depicted in FIG. 18 (Steps S1 to S9).

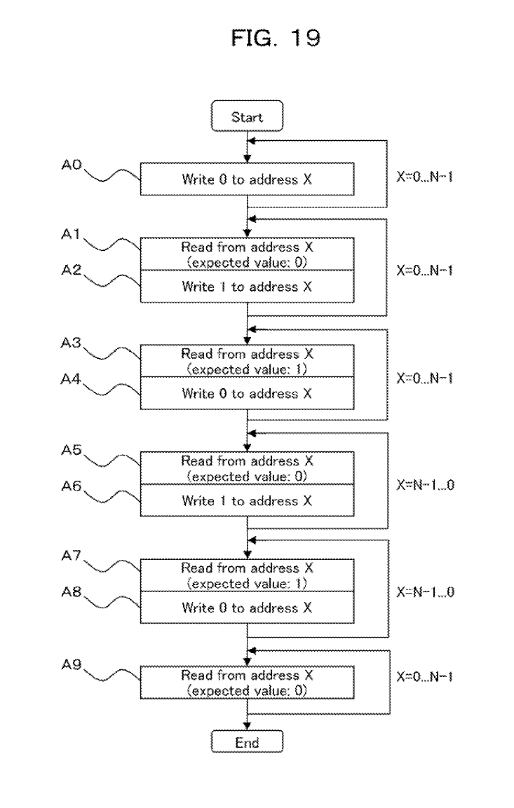

First, a test and repair for the redundant memories 101A are performed (Steps S1 to S6). More specifically, a defect evaluation test for each of the redundant memories 101A is performed by the memory BIST circuit 110, using a defect evaluation memory test pattern, which will be described later with reference to FIG. 19. Then, a failed location (e.g., the address) where a defect arises in the redundant memory 101A is obtained as defect location information, by the defect location information obtainment circuit 120 (Step S1).

If a defect arises in the redundant memory 101A (the “Defective” route from Step S2), it is determined whether that defect can be repaired, as in the manner described above with reference to FIGS. 16A to 16C (Step S3). If a repair is possible (the “Repairable” route from Step S3), repair information is generated from the defect location information and the resultant repair information is written to the FUSE 130. The memory cell in the failed location is then replaced with a spare memory cell for repairing the failed memory cell (Step S4). If a repair is not possible (the “Not reparable” route from Step S3), it is determined that the LSI 100B is defective (NG) (Step S6) and test is terminated.

If no defect arises in the redundant memory 101A (the “Not defective” route from Step S2), or after a repair is performed in Step S4, it is determined that the processing is completed for all of the redundant memories 101A (Step S5). If the processing has been completed for not all of the redundant memories 101A (the NO route from Step S5), the flow returns to the processing in Step S1 and processing similar to the above process is performed for unprocessed redundant memories 101A.

If the processing has been completed for all of the redundant memories 101A (the YES route from Step S5), a test for all of the memories 101 and 101A is performed (Steps S6 to S9). More specifically, a defect evaluation test for each of the memories 101 or 101A is performed by the memory BIST circuit 110, using a defect evaluation memory test pattern, which will be described later with reference to FIG. 19 (Step S7).

If a defect arises in the memory 101 or 101A (the “Defective” route from Step S8), it is determined that the LSI 100B is defective (NG) (Step S6) and test is terminated. In contrast, if no defect arises in the memory 101 or 101A (the “Not defective” route from Step S8), it is determined that the processing is completed for all of the memories 101 and 101A (Step S9). If the processing has been completed for not all of the memories 101 and 101A (the NO route from Step S9), the flow returns to the processing in Step S7 and processing similar to the above process is performed for unprocessed memories 101 or 101A.

### (3) MEMORY TEST PATTERN FOR DEFECT EVALUATION

Here, an example of a typical defect evaluation memory test pattern which is used during a test of a memory will be described with reference to the flowchart depicted in FIG. 19 (Steps A0 to A9). Firstly, a value “0” is written to an address X in a memory under the test, where X=0, 1, . . . , and N−1, in this order (Step A0). After writing the value “0” to all of the addresses 0 to N−1, data is read from the address X, the read data is compared against an expected value of “0”, and a value “1” is written to the address X, where X=0, 1, . . . , and N−1, in this order (Steps A1 and A2).

After writing the value “1” to all of the addresses 0 to N−1, data is read from the address X, the read data is compared against an expected value of “1”, and a value “0” is written to the address X, where X=0, 1, . . . , and N−1, in this order (Steps A3 and A4). After writing the value “0” to all of the addresses 0 to N−1, data is read from the address X, the read data is compared against an expected value of “0”, and a value “1” is written to the address X, in the reserved order, i.e., where X=N−1, N−2, . . . , 1, and 0, in this order (Steps A5 and A6).

After writing the value “1” to all of the addresses 0 to N−1, data is read from the address X, the read data is compared against an expected value of “1”, and a value “0” is written to the address X, where X=N−1, N−2, . . . , 1, and 0, in this order (Steps A7 and A8). After writing the value “0” to all of the addresses 0 to N−1, data is read from the address X, the read data is compared against an expected value of “0” (Step A9), and the test is completed.

The defect evaluation memory test pattern is used for comparing addresses in the examined memory in multiple times, to obtain multiple comparison results. As noted above, if a defect arises in a memory cell at a certain address, all of the comparison results obtained in the multiple comparison results may indicate mismatches, or a part of the comparison results may indicate mismatches while others indicate matches.

Accordingly, when a comparison result for each address in a first memory is written to the same address in a second memory, a new comparison result is overwritten to an old comparison result if the previous comparison result has been already written to that address in the second memory. Hence, when a part of the comparison results may indicate mismatches while others indicate matches as described above, if the comparison result that is overwritten the last in the address in the second memory indicates a match, the old comparison result indicating a mismatch is erased and defect location information in the first memory becomes unavailable any more.

One strategy to address this issue is to read a previous comparison result, merge it with a new comparison result, and write the result to another memory. In such a strategy, however, a larger circuit is required to be added to the testing circuit. Further, memory tests wherein data read and comparison are performed in sequence (refer to Step A9 in FIG. 19) cannot be correctly handled in the above merging.

Further, during a defect evaluation test to obtain defect location information of a redundant memory (Step S1 in FIG. 18), it might be possible to simplify a defect evaluation memory test pattern depicted in FIG. 19. However, a simplified defect evaluation memory test pattern may cause an overlook of a defect which can be detected only with a perfect defect evaluation memory test pattern. If a defect is overlooked, a repair of a failed memory cell may fail.

### (4) EMBODIMENTS

### (4-1) First Embodiment

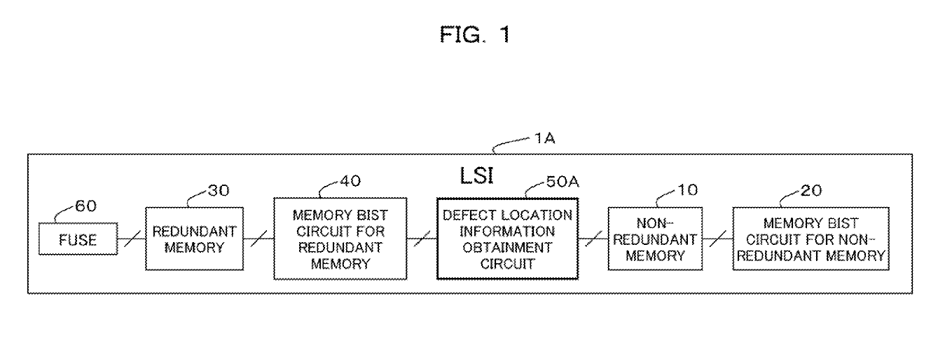

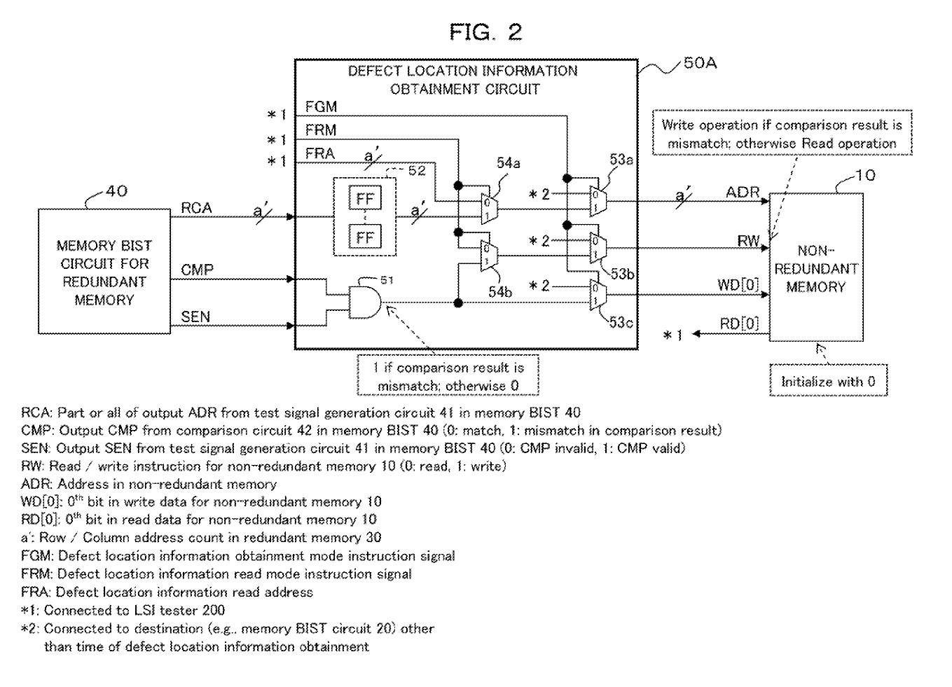

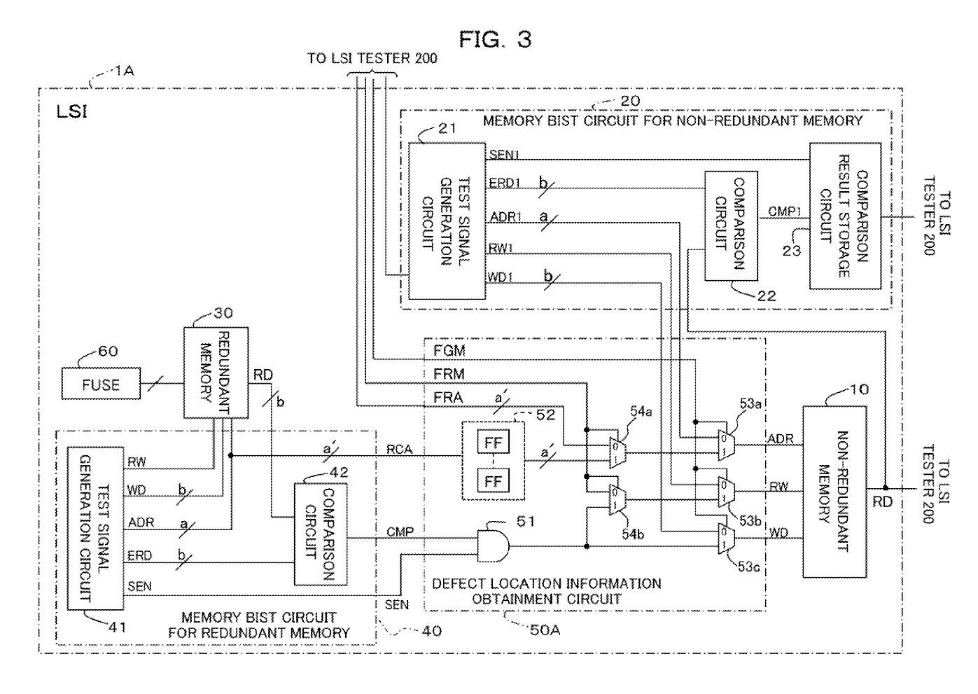

Now, referring to FIGS. 1 to 3, a configuration of an LSI 1A as an integrated circuit including a testing apparatus in a first embodiment will be described. FIG. 1 is a block diagram illustrating a configuration of an integrated circuit LSI 1A including a testing apparatus in a first embodiment; FIG. 2 is a block diagram illustrating a detailed configuration of a defect location information obtainment circuit 50A in the integrated circuit 1A depicted in FIG. 1; and FIG. 3 is a block diagram illustrating a detailed configuration of the integrated circuit 1A depicted in FIGS. 1 and 2.

As depicted in FIG. 1, the LSI 1A in the first embodiment includes a non-redundant memory 10 to be tested and a redundant memory 30. The non-redundant memory 10 does not have a spare memory cell, while the redundant memory 30 has one of the redundant types having spare memory cells depicted in FIGS. 16A to 16C. For the sake of illustration, in the first to sixth embodiments which will be described below, the redundant memory 30 is a row+column redundant type. The LSI 1A in the first embodiment also includes a memory BIST circuit 20 for the non-redundant memory 10, a memory BIST circuit 40 for the redundant memory 30, a defect location information obtainment circuit 50A, and a FUSE 60.

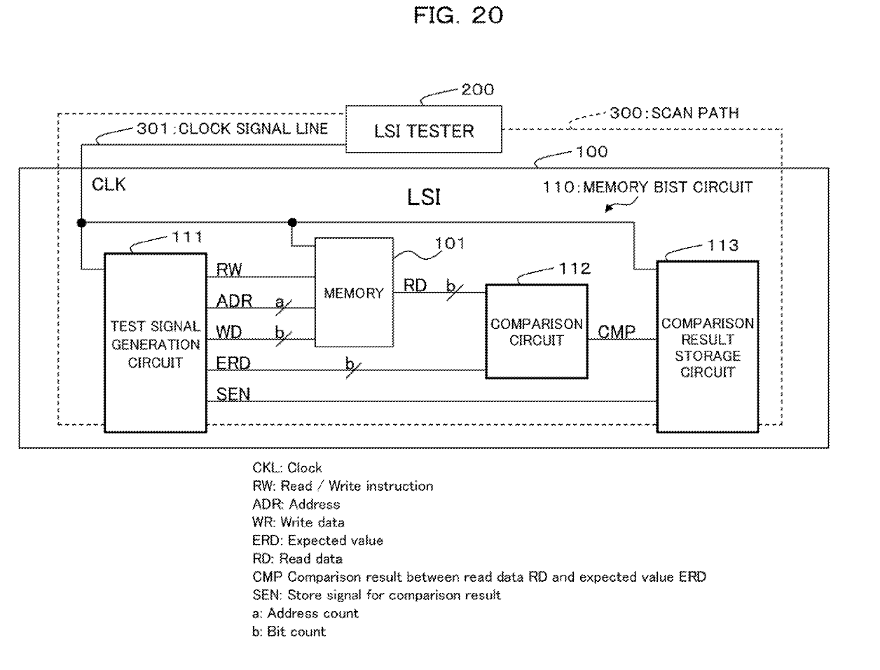

As depicted in FIG. 3, the memory BIST circuit 20 for the non-redundant memory 10 includes a test signal generation circuit 21, a compare circuit 22, and a comparison result storage circuit 23, similarly to the typical memory BIST circuit 110 depicted in FIG. 20.

The test signal generation circuit (second generator) 21 generates a test pattern for the non-redundant memory 10, an expected value ERD1, and a store instruction SEN 1.

The test pattern for the non-redundant memory 10 is an input signal supplied to the non-redundant memory 10 to be tested via selectors 53a to 53c in a defect location information obtainment circuit 50A, which will be described later. Specifically, the test pattern for the non-redundant memory 10 includes a read/write instruction RW1, an address ADR1, and a write data WD1.

The expected value ERD1 is a value of data that is expected to be output from the non-redundant memory 10 in response to the test pattern being supplied to the non-redundant memory 10. The expected value ERD1 is supplied to the compare circuit 22.

The store instruction SEN 1 is a signal for instructing the timing when a result of comparison by the compare circuit 22 is to be stored into the comparison result storage circuit 23.

The compare circuit (second comparator) 22 compares the expected value ERD1 generated by the test signal generation circuit 21, against the data (i.e., the read data RD[0:b-1]) output from the non-redundant memory 10 in response to the test pattern being supplied to the non-redundant memory 10. The compare circuit 22 outputs, as a comparison result CMP1, a value “0”, for example, if the expected value ERD1 matches the read data RD, and outputs a value “1”, for example, if they do not match. During a test of the non-redundant memory 10, a test pattern is generated by the test signal generation circuit 21 using a defect evaluation memory test pattern depicted in FIG. 19, and a comparison is made by the compare circuit 22 for each test pattern.

The comparison result storage circuit 23 stores a comparison result CMP1 from the compare circuit 22, in response to a store instruction SEN1 from the test signal generation circuit 21. More specifically, the comparison result storage circuit 23 stores a value indicating whether or not a mismatch is found in at least one of the multiple comparison results obtained by the compare circuit 22. For example, the comparison result storage circuit 23 stores the value “1” when a mismatch is found in at least one of the multiple comparison results obtained by the compare circuit 22, while storing the value “0” if no mismatch is found, as a comparison result.

Note that the comparison result storage circuit 23 does not have to capture the comparison result CMP1 from the compare circuit 22, and it actually stores the comparison result CMP1 from the compare circuit 22 at rising of the store instruction SEN1 from the test signal generation circuit 21. That is, the compare circuit 22 makes a comparison, in a cycle next to the cycle when read data RD is read from the non-redundant memory 10, in response to a read instruction. Accordingly, the test signal generation circuit 21 generates the store instruction SEN1 such that the comparison result CMP1 from the compare circuit 22 is captured by the comparison result storage circuit 23 in the next cycle.

Once the test of the non-redundant memory 10 is completed, the LSI tester 200 connected to the memory BIST circuit 20 for the non-redundant memory 10 reads comparison results in the comparison result storage circuit 23. The LSI tester 200 determines that the non-redundant memory 10 is defective, and the examined LSI 1A is determined as defective if “at least one mismatch is found” in the comparison results that are read.

The LSI tester 200 determines the examined non-redundant memory 10 as non-defective if “no mismatch is found” in the comparison results that are read. The non-redundant memory 10 that is assured to be from a defect is used as a storage for comparison results during a test of the redundant memory 30, as will be described later. At this time, the memory BIST circuit 20 (test signal generation circuit 21) functions as an initializer that writes an initial value, e.g., a value “0”, to each memory cell in the non-redundant memory 10 before writing comparison results to the non-redundant memory 10, during a test of the redundant memory 30.

As depicted in FIG. 3, the memory BIST circuit 40 for the redundant memory 30 includes a test signal generation circuit 41 and a comparison result storage circuit 42, similarly to the typical memory BIST circuit 110 depicted in FIG. 20.

The test signal generation circuit (first generator) 41 generates a test pattern for the redundant memory 30, an expected value ERD, and a store instruction SEN.

The test pattern for the redundant memory 30 is an input signal to be supplied to the redundant memory 30 to be tested, and particularly is, a read/write instruction RW, an address ADR, and write data WD.

The expected value ERD is a value of data that is expected to be output from the redundant memory 30 in response to the test pattern being supplied to the redundant memory 30. The expected value ERD is supplied to the compare circuit 42.

The store instruction SEN is a signal for instructing the timing when a result of comparison by the compare circuit 42 is to be stored into the non-redundant memory 10.

The compare circuit (first comparator) 42 compares the expected value ERD generated by the test signal generation circuit 41, against the data output (i.e., the read data RD) from the redundant memory 30 in response to the test pattern being supplied to the redundant memory 30. The compare circuit 42 outputs, as a comparison result CMP, a value “0”, for example, if the expected value ERD matches the read data RD, and outputs a value “1”, for example, if they do not match. During a test of the redundant memory 30, a test pattern is generated by the test signal generation circuit 41 using a defect evaluation memory test pattern depicted in FIG. 19, and a comparison is made by compare circuit 42 for each test pattern.

Note that the memory BIST circuit 40 for the redundant memory 30 is also configured similarly to the typical memory BIST circuit 110 depicted in FIG. 20, and the test signal generation circuit 41 generates a store instruction SEN at the same timing when the typical memory BIST circuit 110 generates a store instruction SEN. That is, the compare circuit 42 makes a comparison, in a cycle next to the cycle when read data RD is read from the redundant memory 30, in response to a read instruction. Accordingly, the test signal generation circuit 41 generates the store instruction SEN such that the comparison result CMP from the compare circuit 42 is captured to the storage (non-redundant memory 10) in the next cycle via a defect location information obtainment circuit 50A, which will be described later. The store instruction SEN instructs capture of the comparison result CMP to the non-redundant memory 10 when its value is “1”.

If a defect arises during a test of the redundant memory 30 by the memory BIST circuit 40, i.e., if the comparison result from the compare circuit 42 indicates a mismatch, the defect location information obtainment circuit (write controller) 50A writes location information in the redundant memory 30 where the comparison result is produced, to the non-redundant memory 10, while relating the location information to the comparison result. In contrast, the defect location information obtainment circuit 50A suppresses the comparison result from being written to the non-redundant memory 10, if the comparison result from the compare circuit 42 indicates a match.

If the comparison result from the compare circuit 42 indicates a mismatch, the defect location information obtainment circuit 50A writes, to a location in the non-redundant memory 10 corresponding to the location in the redundant memory 30 where the comparison result is produced, a value “1”, as the comparison result, which is different from the initial value “0” set by the non-redundant memory 10 during the initialization processing. Thereby, the defect location information obtainment circuit 50A writes the comparison result to the non-redundant memory 10, while relating it to the location information in the redundant memory 30 where the comparison result is produced, i.e., defect location information (row+column address).

More specifically, in the defect location information obtainment circuit 50A of first embodiment, if the result of the comparison by the compare circuit 42 between the expected value ERD and the data RD specified with the address ADR and read from the redundant memory 30 indicates a mismatch, the row+column address contained in the address ADR is extracted as the defect location information. The value “1” different from the initial value “0” is written as write data WD[0], to a memory cell corresponding to the address ADR (row+column address RCA) in a certain bit (0^{th} bit in the first embodiment) in the non-redundant memory 10. Thereby, the indication in that the defect arises in the memory cell in the address ADR (row+column address RCA) in the redundant memory 30 is written to the non-redundant memory 10, for obtainment of the defect location information in the redundant memory 30.

As depicted in FIG. 2, the defect location information obtainment circuit 50A in the first embodiment functioning as described above includes an AND gate 51, a flip flop (FF) 52, and selectors 53a, 53b, 53c, 54a, and 54b.

The AND gate 51 outputs a logical AND between the comparison result CMP from the compare circuit 42 in the memory BIST circuit 40 for a redundant memory and the store instruction SEN from the test signal generation circuit 41 in that memory BIST circuit 40. As set forth above, the comparison result CMP assumes a value “0” when the expected value ERD and the read data RD match, while assuming the value “1” when the expected value ERD and the read data RD does not match. The store instruction SEN assumes a value “1” at the timing when the comparison result CMP is captured to the non-redundant memory 10, while assuming a value “0” at other timing. Accordingly, the output from the AND gate 51 is “1”, if a defect arises in the redundant memory 30, the comparison result CMP from the compare circuit 42 is “1”, and the store instruction SEN is “1”, while assuming “0” otherwise.

The FF 52 retains address information RCA from the memory BIST circuit 40 (test signal generation circuit 41) for a single cycle, and then outputs it. The compare circuit 42 in the memory BIST circuit 40 makes a comparison, in a cycle next to the cycle when read data RD is read from the redundant memory 30, in response to a read instruction. The timing of an input of the comparison result CMP from the compare circuit 42 is synchronized with the address information RCA corresponding to the comparison result CMP, by retaining the address information RCA to the FF 52 for a single cycle. Note that the address information RCA is a part or all of an address ADR generated by the test signal generation circuit 41 in the memory BIST circuit 40, and a row+column address in the present embodiment.

The selectors 53a, 53b, and 53c select one of the respective two inputs, in accordance with a defect location information obtainment mode instruction signal FGM from the LSI tester 200 connected to the LSI 1A during a test. The defect location information obtainment mode instruction signal FGM assumes a value “1” for making the defect location information obtainment circuit 50 obtain defect location information, assuming a value “0” otherwise. The memory BIST circuit 20 for a non-redundant memory may be connected to the non-redundant memory 10 in occasions other than a defect location information obtainment, as depicted in FIG. 3, for example. However, a circuit other than the memory BIST circuit 20 for a non-redundant memory may be connected to the non-redundant memory 10 via the selectors 53a, 53b, and 53c.

The selector 53a selects an address ADR1 from the memory BIST circuit 20 for a non-redundant memory, and outputs it to the non-redundant memory 10 as an address ADR, as depicted in FIG. 3, for example, when instruction signal FGM is “0”. In contrast, the selector 53a selects address information from a selector 54a, which will be described later, and outputs it to the non-redundant memory 10 as the address ADR, when instruction signal FGM is “1”.

The selector 53b selects a read/write instruction RW1 from the memory BIST circuit 20 for a non-redundant memory, and outputs it to the non-redundant memory 10 as a read/write instruction RW, as depicted in FIG. 3, for example, when instruction signal FGM is “0”. In contrast, the selector 53b selects a read/write instruction from a selector 54b, which will be described later, and outputs it to the non-redundant memory 10 as the read/write instruction RW, when instruction signal FGM is “1”.

The selector 53c selects write data WD1 from the memory BIST circuit 20 for a non-redundant memory, and outputs it to the non-redundant memory 10 as write data WD[0:b-1], as depicted in FIG. 3, for example, when instruction signal FGM is “0”. In contrast, the selector 53c selects the comparison result CMP from the AND gate 51, and outputs it to the non-redundant memory 10 as the write data WD[0] in the 0^{th} bit, when instruction signal FGM is “1”.

The selectors 54a and 54b select one of the respective two inputs, in accordance with a defect location information read mode instruction signal FRM from the LSI tester 200 connected to the LSI 1A during a test. The defect location information read mode instruction signal FRM assumes a value “0” for instructing read of defect location information from the non-redundant memory 10, whereas assuming a value “1” for instructing a writing of defect location information to the non-redundant memory 10.

The selector 54a selects a defect location information read address FRA specified by the LSI tester 200, and outputs it to the selector 53a as address information, when the instruction signal FRM is “0”. In contrast, the selector 54a selects address information RCA from the FF 52, and outputs it to the selector 53a as address information, when the instruction signal FRM is “1”.

When the instruction signal FRM is “0”, the selector 54b selects the instruction signal FRM with the value “0”, and outputs it to the selector 53b as a read/write instruction. In contrast, the selector 54b selects the comparison result CMP from the AND gate 51, and outputs it to the selector 53b as a read/write instruction, when the instruction signal FRM is “1”.

In FIGS. 2 and 3, “a” indicates the address count in the redundant memory 30, “b” indicates the bit count, and “a′” indicates the row+column address count in the redundant memory 30. A read/write instruction RW of “0” instructs read from the non-redundant memory 10, whereas a read/write instruction RW of “1” instructs write to the non-redundant memory 10.

Further, when the instruction signal FGM is set to “1” and the instruction signal FRM is set to “0”, a read instruction RW with a value “0” and the defect location information read address FRA from the LSI tester 200 are input to the non-redundant memory 10. Accordingly, the value in the 0^{th} bit in the address FRA is output from the non-redundant memory 10 to the LSI tester 200, as read data RD[0]. In this case, when the read data RD[0] is “1”, it is determined that a defect is found in a memory cell in the address FRA in the redundant memory 30. In contrast, when the read data RD[0] is “0”, it is determined that no defect is found in a memory cell in the address FRA in the redundant memory 30. In other words, the address where the read data RD[0] is set to “1” represents defect location information in the redundant memory 30.

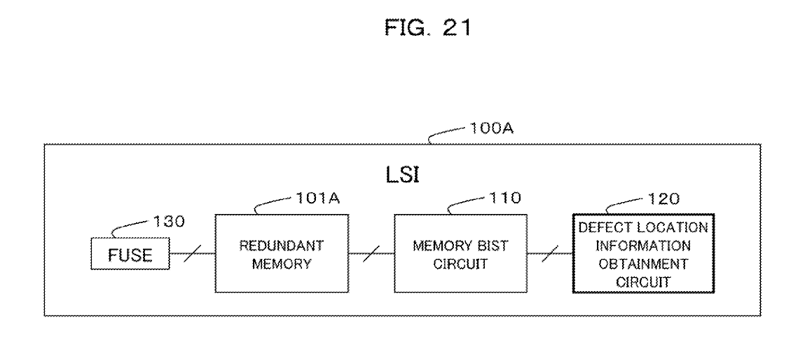

The FUSE (non-volatile storage device) 60 functions as repair unit that replaces a memory cell in a failed location specified based on the comparison result CMP and the defect location information stored in the non-redundant memory 10, with a spare memory cell. Note that the FUSE 60 is configured similarly to the FUSE 130 which is described above with reference to FIG. 21, which can retain information even after power-down and can be switched by means of a physical or electric operation within the LSI to replace the memory cell in the failed location with a spare memory cell.

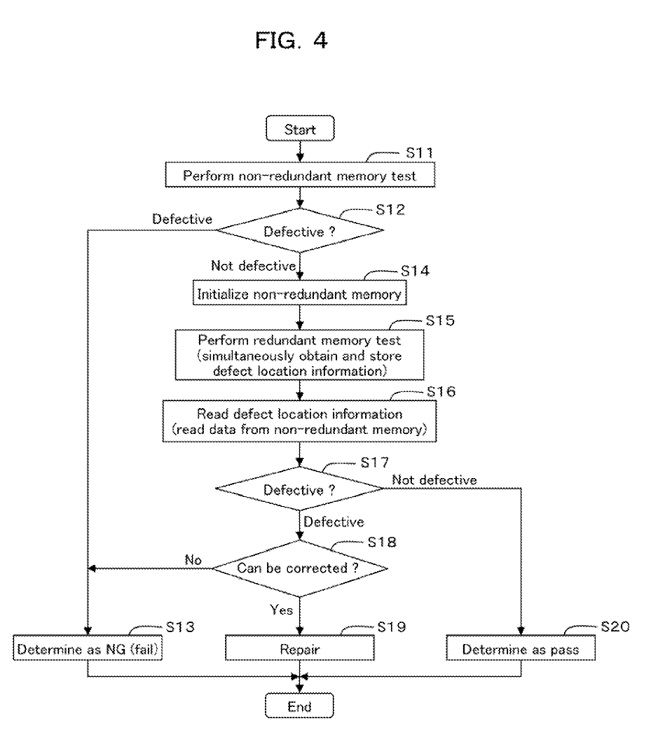

Next, a memory test procedure by the LSI 1A depicted in FIGS. 1 to 3 will be described with reference to the flowchart depicted in FIG. 4 (Steps S11 to S20).

First, a test of the non-redundant memory 10 is performed using the memory BIST circuit 20 (Step S11). During the test, an instruction signal FGM from the LSI tester 200 is set to “0”. Thereby, an address ADR1 from the memory BIST circuit 20 is output to the non-redundant memory 10 via the selector 53a, as an address ADR. Further, a read/write instruction RW1 from the memory BIST circuit 20 is output to the non-redundant memory 10 via the selector 53b, as a read/write instruction RW. Further, write data WD1 from the memory BIST circuit 20 is output to the non-redundant memory 10 via the selector 53c, as write data WD[0:b-1].

In this case, a defect evaluation test of the non-redundant memory 10 is performed by the memory BIST circuit 20, using a defect evaluation memory test pattern depicted in FIG. 19, for example.

Specifically, while the LSI tester 200 is connected to the LSI 1A, after an initialization, a test of the non-redundant memory 1 is performed, in response to the test signal generation circuit 21 suitably generating a test pattern, an expected value ERD1, and a store instruction SEN 1. The comparison result CMP1 from the compare circuit 22 is then stored in the comparison result storage circuit 23.

After the test of the non-redundant memory 10 is completed, the LSI tester 200 reads comparison results in the comparison result storage circuit 23. The LSI tester 200 determines that the non-redundant memory 10 is defective (the “Defective” route from Step S12), the examined LSI 1A is determined as defective (NG) (Step S13), and the test is terminated, if “at least one mismatch is found” in the comparison results that are read.

In contrast, the LSI tester 200 determines the examined LSI 100 as non-defective (the “Not defective” route from Step S12) if “no mismatch is found” in the comparison results that are read. An initialization is then performed using the memory BIST circuit 20 (test signal generation circuit 21) to write an initial value “0” into the respective memory cells in the non-redundant memory 10 (Step S14).

Thereafter, the instruction signal FGM from the LSI tester 200 is set to “1”, and the instruction signal FRM from the LSI tester 200 is set to “1”. Thereby, address information RCA (row+column address) from the memory BIST circuit 40 is output to the non-redundant memory 10 via the FF 52 and the selectors 54a and 53a, as an address ADR. Further, an output from the AND gate 51 is output to the non-redundant memory 10 via the selectors 54b and 53b, as a read/write instruction RW. Further, the comparison result CMP from the AND gate 51 is output to the non-redundant memory 10 via the selector 53c, as write data WD[0].

In this case, a defect evaluation test of the redundant memory 30 is performed by the memory BIST circuit 40, using a defect evaluation memory test pattern depicted in FIG. 19, for example (Step S15).

Specifically, while the LSI tester 200 is connected to the LSI 1A, a test of the redundant memory 30 is performed, in response to the test signal generation circuit 41 suitably generating a test pattern, an expected value ERD, and a store instruction SEN. Simultaneously, the comparison result CMP from the compare circuit 42 is written to the non-redundant memory 10 via the defect location information obtainment circuit 50A, while being related to the address information RCA in the redundant memory 30 where the comparison result CMP is produced. Here, the defect location information obtainment circuit 50A has been assured to be free from a defect and has been initialized with the initial value “0”.

At this time, in the defect location information obtainment circuit 50A, the output from the AND gate 51 changes to “1”, only when the comparison result from the compare circuit 42 indicates a mismatch (defective), the CMP with a value of “1” is output, and the store instruction SEN from the test signal generation circuit 41 changes to “1”. In response to the output from the AND gate 51 changing to “1”, a read/write instruction RW with a value “1” is output to the non-redundant memory 10 via the selectors 54b and 53b. Further, the row+column address RCA in the redundant memory 30 where the comparison result is produced is output via the FF 52, and the selectors 54a and 53a, as the address ADR in the non-redundant memory 10. As a result, the output “1” from the AND gate 51 is written to the memory cell corresponding to the row+column address RCA in the 0^{th} bit in the non-redundant memory 10 via the selector 53c, as write data WD[0]. Thereby, the indication in that the defect arises in the memory cell in the address ADR (row+column address RCA) in the redundant memory 30 is written to the non-redundant memory 10, for obtainment of the defect location information in the redundant memory 30.

In contrast, in the defect location information obtainment circuit 50A, the output from the AND gate 51 changes to “0”, when the comparison result from the compare circuit 42 indicates a match (non-defective) and the CMP with a value of “0” is output, regardless of the value of the store instruction SEN from the test signal generation circuit 41. In response to the output from the AND gate 51 changing to “0”, a read instruction RW with a value “0” is output to the non-redundant memory 10 via the selectors 54b and 53b. This suppresses the value “0” to be written to the non-redundant memory 10 as a comparison result CMP.

Once the defect evaluation test of the redundant memory 30 is completed, the instruction signal FGM from the LSI tester 200 is set to “1”, and the instruction signal FRM from the LSI tester 200 is set to “0”. Thereby, the defect location information read address FRA specified by the LSI tester 200 is output to the non-redundant memory 10 via the selectors 54a and 53a, as an address ADR. Further, the value“0” of the instruction signal FR, i.e., the read instruction RW with a value “0”, is output to the non-redundant memory 10 via the selectors 54b and 53b. As a result, the value in the 0^{th} bit in the address FRA is output from the non-redundant memory 10 to the LSI tester 200, as read data RD[0] (Step S16). In this case, as noted above, when the read data RD[0] is “1”, it is determined that a defect is found in a memory cell in the address FRA in the redundant memory 30. In contrast, when the read data RD[0] is “0”, it is determined that no defect is found in a memory cell in the address FRA in the redundant memory 30.

If the defect location information read from the non-redundant memory 10 indicates that no defect arises in the redundant memory 30 (the “Not defective” route from Step S17), it is determined that the LSI 1A is non-defective (Step S20) and test is terminated. In contrast, if the defect location information read from the non-redundant memory 10 indicates that a defect arises in the redundant memory 30 (the “Defective” route from Step S17), it is determined whether that defect can be repaired, as in the manner described above with reference to FIGS. 16A to 16C (Step S18). If a repair is possible (the “Repairable” route from Step S18), repair information is generated from the defect location information and the resultant repair information is written to the FUSE 60. The memory cell in the failed location is then replaced with a spare memory cell for repairing the failed memory cell (Step S19). If a repair is not possible (the “Not reparable” route from Step S18), it is determined that the LSI 1A is defective (NG) (Step S13) and test is terminated.

In accordance with the LSI 1A including the testing apparatus of the above-described first embodiment, only when a comparison result obtained for the redundant memory 30 is a mismatch (defective), a value indicating the defect is written to a memory cell at an address corresponding to the address where the defect arises in the redundant memory 30, in the non-redundant memory 10. Further, the operation to write the value “0” indicating that the comparison result is a match (non-defective) is suppressed. Hence, once a value “1” indicating a defect is written, and that value is never overwritten with a value “0”.

Further, the initial value “0” is set to the non-redundant memory 10, and if a comparison result obtained for the redundant memory 30 is a mismatch (defective), no value is written to the non-redundant memory 10. Accordingly, the initial value “0” is kept in memory cells at addresses in the non-redundant memory 10 corresponding to addresses where no defect is found in the redundant memory 30.

Therefore, defect location information can be obtained in a reliable manner using a defect evaluation memory test pattern depicted in FIG. 19, for example. Specifically, even when read data and an expected value are compared in multiple times for each address, an appropriate comparison result (whether a mismatch is found at least once) can be obtained in a reliable manner. A defect occurrence location in the redundant memory 30 is obtained reliably during a test of the redundant memory 30 on the LSI 1A. Hence, a memory cell in the failed location in the redundant memory 30 can be identified and the redundant memory 30 can be repaired reliably by replacing the memory cell in the failed location with a spare memory cell.

Further, in accordance with the LSI 1A including the testing apparatus of the above-described first embodiment, the non-redundant memory 10 is tested for assuring that the non-redundant memory 10, for which no defect location information is required, is free from a defect. Then, a test and obtainment of defect location information are performed for the redundant memory 30, using the non-redundant memory 10 has been assured to be free from a defect. Accordingly, since defect location information of the redundant memory 30 is obtained using the non-redundant memory 10 on the LSI 1A, the defect location information is not required to be stored in a circuit external to the LSI, such as the LSI tester 200, for obtaining the defect location information. Accordingly, defect location information can be obtained when a test is done on the LSI 1A at a clock rate higher than the performance of the LSI tester 200. As a result, a memory defect that arises only at higher clock rates can be identified.

### (4-2) Second Embodiment

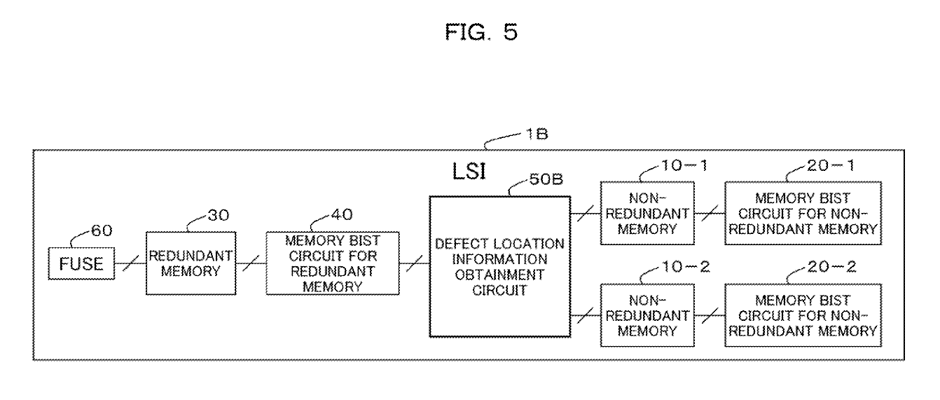

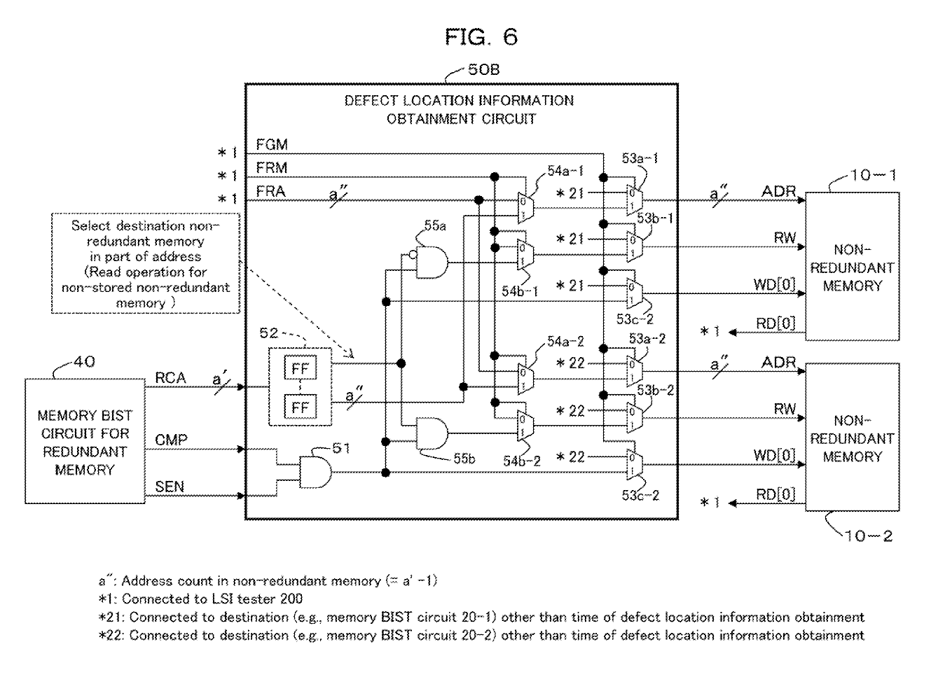

Now, referring to FIGS. 5 and 6, a configuration of an LSI 1B as an integrated circuit including a testing apparatus in a second embodiment will be described. FIG. 5 is a block diagram illustrating a configuration of an LSI 1B including a testing apparatus in the second embodiment, and FIG. 6 is a block diagram illustrating a detailed configuration of defect location information obtainment circuit 50B in the LSI 1B depicted in FIG. 5. Note that descriptions of the elements having the same reference symbols in the drawings as the elements described previously will be emitted since they refer to the same or substantially the same elements set forth previously.

As depicted in FIG. 5, the LSI 1B in the second embodiment includes two non-redundant memories 10-1 and 10-2, and a redundant memory 30 similar to that in the first embodiment. The two non-redundant memories 10-1 and 10-2 are both configured similarly to the non-redundant memory 10 in the first embodiment. The LSI 1B in the second embodiment also includes the memory BIST circuit 20-1 for the non-redundant memory 10-1, the memory BIST circuit 20-2 for the non-redundant memory 10-2, a memory BIST circuit 40 similar to that in the first embodiment, a defect location information obtainment circuit 50B, and a FUSE 60 similar to that in the first embodiment. The two memory BIST circuits 20-1 and 20-2 are both configured similarly to the memory BIST circuit 20 in the first embodiment.

If a comparison result from the compare circuit 42 indicates a mismatch, the defect location information obtainment circuit (write controller) 50B selects one of the two non-redundant memories 10-1 and 10-2, in accordance with a part of the address information RCA (row+column address) where the comparison result is produced in the redundant memory 30. The defect location information obtainment circuit 50B writes the value “1” different from the initial value “0” as write data WD[0], to a memory cell corresponding to the address ADR (row+column address) in a certain bit (0^{th} bit in the second embodiment) in the selected non-redundant memory 10-1 or 10-2. Thereby, the defect location information obtainment circuit 50 writes the comparison result to the non-redundant memory 10-1 or 10-2, while relating it to the location information in the redundant memory 30 where the comparison result is produced, i.e., defect location information (row+column address).

As depicted in FIG. 6, the defect location information obtainment circuit 50B in the second embodiment functioning as described above includes selectors 53a-1, 53b-1, 53c-1, 54a-1, and 54b-1, selectors 53a-2, 53b-2, 53c-2, 54a-2, and 54b-2, an inverting AND gate 55a, and an AND gate 55b, in addition to the AND gate 51 and the FF 52 similar to those in the first embodiment.

The selectors 53a-1, 53b-1, 53c-1, 54a-1, and 54b-1 are provided for the non-redundant memory 10-1 and have functions similar to those of the selectors 53a, 53b, and 53c, 54a, and 54b in the first embodiment, respectively, and detailed description thereof will be omitted. Further, the selectors 53a-2, 53b-2, 53c-2, 54a-2, and 54b-2 are provided for the non-redundant memory 10-2 and have functions similar to those of the selectors 53a, 53b, 53c, 54a, and 54b in the first embodiment, respectively, and detailed description thereof will be omitted.

The inverting AND gate 55a outputs a logical AND between an inversion of one bit (e.g., the uppermost bit) in a′-bit address information RCA from the FF 52, and the output from the AND gate 51. In other words, the inverting AND gate 55a outputs the CMP with a value of “1” indicating that the comparison result indicates a mismatch, as a write instruction RW with a value of “1” only if the uppermost bit in the address information RCA is “0”; otherwise outputs a read instruction RW with a value “0”.

The selector 54a-1 selects a defect location information read address FRA specified by the LSI tester 200, and outputs it to the selector 53a-1 as address information, when the instruction signal FRM is “0”. In contrast, the selector 54a-1 selects address information (a″ (=a′-1) address) in the address information RCA from the FF 52, other than the uppermost bit, and outputs it as address information to the selector 53a-1, when the instruction signal FRM is “1”.

When the instruction signal FRM is “0”, the selector 54b-1 selects the instruction signal FRM with the value “0”, and outputs it to the selector 53b-1 as a read/write instruction. In contrast, the selector 54b-2 selects the comparison result CMP from the inverting AND gate 55a, and outputs it to the selector 53b-1 as a read/write instruction, when the instruction signal FRM is “1”.

The AND gate 55b outputs a logical AND between the value of the one bit (e.g., the uppermost bit) in the a′-bit address information RCA from the FF 52, and the output from the AND gate 51. In other words, the AND gate 55b outputs the CMP with a value of “1” indicating that the comparison result indicates a mismatch, as a write instruction RW with a value of “1” only if the uppermost bit in the address information RCA is “1”; otherwise outputs a read instruction RW with a value “0”.

The selector 54a-2 selects a defect location information read address FRA specified by the LSI tester 200, and outputs it to the selector 53a-2 as address information, when the instruction signal FRM is “0”. In contrast, the selector 54a-2 selects address information (a″ address) in the address information RCA from the FF 52, other than the uppermost bit, and outputs it as address information to the selector 53a-2, when the instruction signal FRM is “1”.

When the instruction signal FRM is “0”, the selector 54b-2 selects the instruction signal FRM with the value “0”, and outputs it to the selector 53b-2 as a read/write instruction. In contrast, the selector 54b-2 selects the comparison result CMP from the AND gate 55b, and outputs it to the selector 53b-2 as a read/write instruction, when the instruction signal FRM is “1”.

A memory test of the LSI 1B in the second embodiment configured as described above is performed according to the flowchart depicted in FIG. 4 (Steps S11 to S20), in a manner similar to that in the first embodiment.

In the LSI 1B in the second embodiment, however, in Step S15, if the uppermost bit in the address information RCA from the FF 52 is “0”, the CMP with a value of “1” indicating that the comparison result indicates a mismatch is output to the non-redundant memory 10-1, as a write instruction RW with a value of “1”. At this time, address information (a″ address) in the address information RCA from the FF 52, other than the uppermost bit is output to the non-redundant memory 10-1, as an address ADR. As a result, the output “1” from the AND gate 51 is written to the memory cell corresponding to the a″ address ADR in the 0^{th} bit in the non-redundant memory 10-1, as write data WD[0]. Thereby, the indication in that the defect arises in the memory cell in the address ADR (row+column address RCA) in the redundant memory 30 is written to the non-redundant memory 10-1, for obtainment of the defect location information in the redundant memory 30. Note that, if the uppermost bit in the address information RCA from the FF 52 is “0”, the output from the AND gate 55b is always “0” and a read instruction RW with a value “0” is always output to the non-redundant memory 10-2. As a result, writing of the comparison result to the non-redundant memory 10-2 is suppressed.

Similarly, in the LSI 1B in the second embodiment, in Step S15, if the uppermost bit in the address information RCA from the FF 52 is “0”, the CMP with a value of “1” indicating that the comparison result indicates a mismatch is output to the non-redundant memory 10-2, as a write instruction RW with a value of “1”. At this time, address information (a″ address) in the address information RCA from the FF 52, other than the uppermost bit is output to the non-redundant memory 10-2, as an address ADR. As a result, the output “1” from the AND gate 51 is written to the memory cell corresponding to the a″ address ADR in the 0^{th} bit in the non-redundant memory 10-1, as write data WD[0]. Thereby, the indication in that the defect arises in the memory cell in the address ADR (row+column address RCA) in the redundant memory 30 is written to the non-redundant memory 10-2, for obtainment of the defect location information in the redundant memory 30. Note that, if the uppermost bit in the address information RCA from the FF 52 is “0”, the output from the inverting AND gate 55a is always “0” and a read instruction RW with a value “0” is always output to the non-redundant memory 10-1. As a result, writing of the comparison result to the non-redundant memory 10-1 is suppressed.

The LSI 1B including the testing apparatus of the above-described second embodiment provides advantages and effects similar to those in the first embodiment.

Further, in accordance with the LSI 1B including the testing apparatus in the second embodiment, defect location information of a single redundant memory 30 can be stored across multiple non-redundant memories 10. Accordingly, the address count a′ of a redundant memory 30 greater than the address count a″ of a non-redundant memory 10 can be handled, which enables reliable obtainment of a defect occurrence location in the respective redundant memories 30.

### (4-3) Third Embodiment

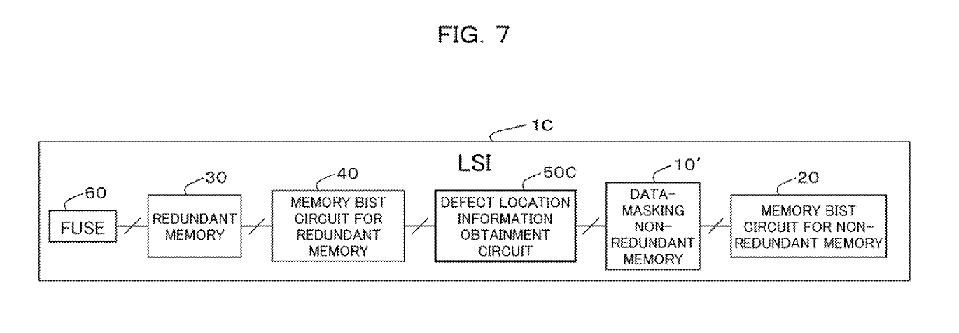

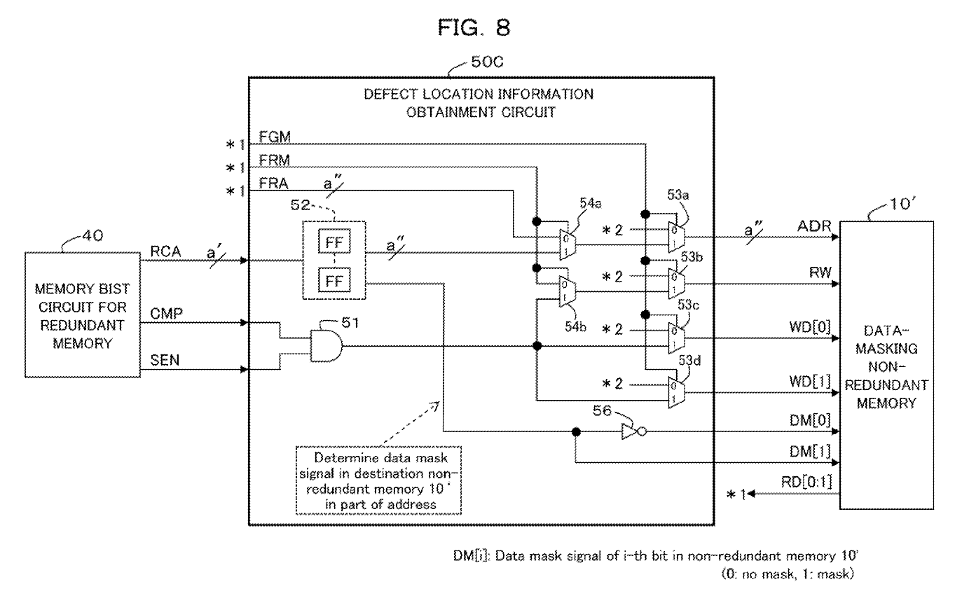

Now, referring to FIGS. 7 and 8, a configuration of an LSI 1C as an integrated circuit including a testing apparatus in a third embodiment will be described. FIG. 7 is a block diagram illustrating a configuration of an LSI 1C including a testing apparatus of the third embodiment, and FIG. 8 is a block diagram illustrating a detailed configuration of defect location information obtainment circuit 50C in the LSI 1C depicted in FIG. 7. Note that descriptions of the elements having the same reference symbols in the drawings as the elements described previously will be emitted since they refer to the same or substantially the same elements set forth previously.

As depicted in FIG. 7, the LSI 1C in the third embodiment includes a non-redundant memory 10′ with a data mask function (data-masking non-redundant memory 10′) and a redundant memory 30 similar to that in the first embodiment. Further, the LSI 1C in the third embodiment includes a defect location information obtainment circuit 50C, in addition to memory BIST circuits 20 and 40 and a FUSE 60 similar to those in the first embodiment.

The data-masking non-redundant memory 10′ basically has a configuration similar to the non-redundant memory 10 in the first embodiment, and additionally has a data mask function for permitting write to a particular bit in a plurality of bits.

For example, as depicted in FIG. 8, for writing data to the 0^{th} and 1^{st} bits in a plurality of bits, data mask signals DM[0] and DM[1] indicating whether data is to be masked are input to the non-redundant memory 10′ in the present embodiment.

If the data mask signal DM[0] is set to “0”, the 0^{th} bit is not masked and writing of data WD[0] to the 0^{th} bit in the non-redundant memory 10′ is permitted. In contrast, if the data mask signal DM[0] is set to “1”, the 0^{th} bit is masked and writing of write data WD[0] to the 0^{th} bit in the non-redundant memory 10′ is prohibited.

Similarly, if the data mask signal DM[1] is set to “0”, the 1^{st} bit is not masked and writing of the write data WD[1] to the 1^{st} bit in the non-redundant memory 10′ is permitted. In contrast, if the data mask signal DM[1] is set to “1”, the 1^{st} bit is masked and writing of write data WD[1] to the 1^{st} bit in the non-redundant memory 10′ is prohibited.

If the comparison result from the compare circuit 42 indicates a mismatch, the defect location information obtainment circuit (write controller) 50C selects the 0^{th} or 1^{st} bit in the non-redundant memory 10′, in accordance with a part of the address information RCA (row+column address) where the comparison result is produced in the redundant memory 30. The selection between the 0^{th} or 1^{st} bit in the non-redundant memory 10′ is made using the data mask function described above. The defect location information obtainment circuit 50C then writes the value “1” different from the initial value “0” to a memory cell corresponding to the address information RCA (row+column address) at the selected bit, as write data WD[0] or WD[1]. Thereby, the defect location information obtainment circuit 50C writes the comparison result to the 0^{th} or 1^{st} bit in the non-redundant memory 10′, while relating it to the location information in the redundant memory 30 where the comparison result is produced, i.e., defect location information (row+column address).

As depicted in FIG. 8, the defect location information obtainment circuit 50C in the third embodiment functioning as described above includes a selector 53d and an inverter element 56, in addition to an AND gate 51, an FF 52, and selectors 53a, 53b, 53c, 54a, and 54b similar to those in the first embodiment.

The selector 53d is provided so as to be parallel to the selector 53c, and selects write data from the memory BIST circuit 20 for a non-redundant memory, and outputs it to the non-redundant memory 10′, in the manner similar to the selector 53c. In contrast, the selector 53d selects the comparison result CMP from the AND gate 51, and outputs it to the non-redundant memory 10′ as the write data WD[1] in the 1^{st} bit, when instruction signal FGM is “1”.

The inverter element 56 inverts the value of one bit (e.g., the uppermost bit) in a′-bit address information RCA from the FF 52, and outputs the inversion to the non-redundant memory 10′ as a data mask signal DM[0]. Further, in the present embodiment, the value of the one bit (e.g., the uppermost bit) in the a′-bit address information RCA from the FF 52 is output to the non-redundant memory 10′ as a data mask signal DM[1].

Further, the selector 54a in the third embodiment selects address information (a″ (=a′-1) address) in the address information RCA from the FF 52, other than the uppermost bit, and outputs it as address information to the selector 53a, when the instruction signal FRM is “1”.

A memory test of the LSI 1C in the third embodiment configured as described above is performed according to the flowchart depicted in FIG. 4 (Steps S11 to S20), in a manner similar to that in the first embodiment.

In the LSI 1C in the third embodiment, however, in Step S15, if the uppermost bit in the address information RCA from the FF 52 is “0”, the data mask signal DM[0] with a value “1” and DM[1] with a value “0” are output to the non-redundant memory 10′. Thereby, in the non-redundant memory 10′, writing of write data WD[0] to the 0^{th} bit is prohibited, while permitting writing of write data WD[1] to the 1^{st} bit.

In response to the output from the AND gate 51 changing to “1”, a read/write instruction RW with a value “1” is output to the non-redundant memory 10 via the selectors 54b and 53b. At this time, address information (a″ address) in the address information RCA from the FF 52, other than the uppermost bit is output to the non-redundant memory 10′, as an address ADR. As a result, the output “1” from the AND gate 51 is written to the memory cell corresponding to the a″ address ADR in the 0^{th} bit in the non-redundant memory 10′ via the selector 53d, as write data WD[1]. Thereby, the indication in that the defect arises in the memory cell in the address ADR (row+column address RCA) in the redundant memory 30 is written to the 1^{st} bit in the non-redundant memory 10′, for obtainment of the defect location information in the redundant memory 30.

Note that the output “1” from the AND gate 51 is also output to the non-redundant memory 10′ via the selector 53c, as write data WD[0]. However, when the uppermost bit in the address information RCA from the FF 52 is “0”, writing of write data WD[0] to the 0^{th} bit is prohibited in the non-redundant memory 10′, as set forth above. Accordingly, the output “1” from the AND gate 51 is not written to the 0^{th} bit in the non-redundant memory 10′.

Similarly, in the LSI 1C in the third embodiment, in Step S15, if the uppermost bit in the address information RCA from the FF 52 is “1”, the data mask signal DM[0] with a value “0” and DM[1] with a value “1” are output to the non-redundant memory 10′. Thereby, in the non-redundant memory 10′, writing of write data WD[0] to the 0^{th} bit is permitted, while prohibiting writing of write data WD[1] to the 1^{st} bit.

In response to the output from the AND gate 51 changing to “1”, a read/write instruction RW with a value “1” is output to the non-redundant memory 10′ via the selectors 54b and 53b. At this time, address information (a″ address) in the address information RCA from the FF 52, other than the uppermost bit is output to the non-redundant memory 10′, as an address ADR. As a result, the output “1” from the AND gate 51 is written to the memory cell corresponding to the a″ address ADR in the 0^{th} bit in the non-redundant memory 10′ via the selector 53d, as write data WD[0]. Thereby, the indication in that the defect arises in the memory cell in the address ADR (row+column address RCA) in the redundant memory 30 is written to the 0^{th} bit in the non-redundant memory 10′, for obtainment of the defect location information in the redundant memory 30.

Note that the output “1” from the AND gate 51 is also output to the non-redundant memory 10′ via the selector 53d, as write data WD[1]. However, when the uppermost bit in the address information RCA from the FF 52 is “0”, writing of write data WD[1] to the 1^{st} bit is prohibited in the non-redundant memory 10′, as set forth above. Accordingly, the output “1” from the AND gate 51 is not written to the 1^{st} bit in the non-redundant memory 10′.

The LSI 1C including the testing apparatus of the above-described third embodiment provides advantages and effects similar to those in the first embodiment.

Further, in accordance with the LSI 1C including the testing apparatus in the third embodiment, defect location information of a single redundant memory 30 can be stored across different bits in a non-redundant memory 10′. Accordingly, as in the second embodiment, the address count a′ of a redundant memory 30 greater than the address count a″ of a non-redundant memory 10′ can be handled, which enables reliable obtainment of a defect occurrence location in the redundant memory 30.

### (4-4) Fourth Embodiment

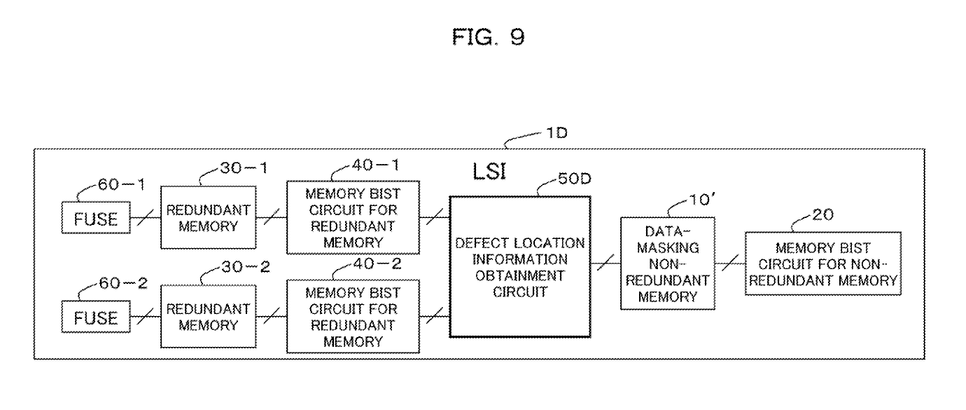

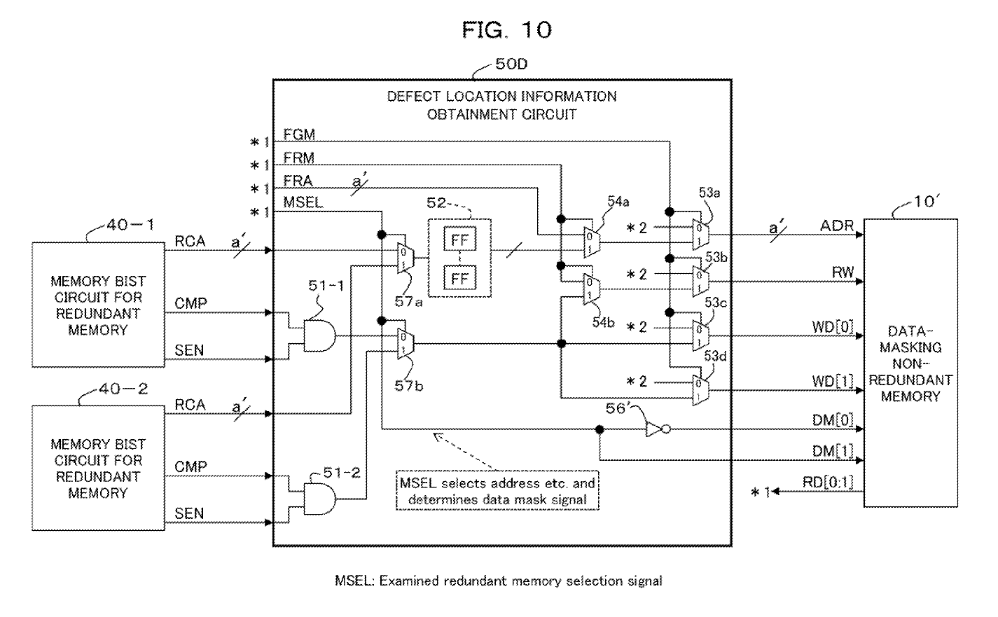

Now, referring to FIGS. 9 and 10, a configuration of an LSI 1D as an integrated circuit including a testing apparatus in a fourth embodiment will be described. FIG. 9 is a block diagram illustrating a configuration of an LSI 1D including a testing apparatus in the fourth embodiment, and FIG. 10 is a block diagram illustrating a detailed configuration of defect location information obtainment circuit 50D in the LSI 1D depicted in FIG. 9. Note that descriptions of the elements having the same reference symbols in the drawings as the elements described previously will be emitted since they refer to the same or substantially the same elements set forth previously.

As depicted in FIG. 9, the LSI 1D in the fourth embodiment includes a non-redundant memory 10′ with a data mask function (data-masking non-redundant memory 10′) similar to that in the third embodiment, and two redundant memories 30-1 and 30-2. The two redundant memories 30-1 and 30-2 are both configured similarly to the redundant memory 30 in the first embodiment. Further, the LSI 1D in the fourth embodiment includes a memory BIST circuit 20 similar to that in the first embodiment, a memory BIST circuit 40-1 for the redundant memory 30-1, a memory BIST circuit 40-2 for the redundant memory 30-2, a defect location information obtainment circuit 50D, and FUSEs (repair units) 60-1 and 60-2 corresponding to the two redundant memories 30-1 and 30-2, respectively. The two memory BIST circuits 40-1 and 40-2 are both configured similarly to the memory BIST circuit 4 in the first embodiment. The two FUSEs 60-1 and 60-2 are both configured similarly to the FUSE 60 in the first embodiment.

The defect location information obtainment circuit (write controller) 50D selects a bit (the 0^{th} or 1^{st} bit) in the non-redundant memory 10′, which is related to the one of the two memory BIST circuits 40-1 and 40, in advance, if a comparison result from a compare circuit 42 in one of the two memory BIST circuits 40-1 and 40-2 is a mismatch. The selection between the 0^{th} or 1^{st} bit in the non-redundant memory 10′ is made using the data mask function described above. In the present embodiment, the memory BIST circuits 40-1 and 40-2 are related to the 1^{st} bit and the 0^{th} bit in the non-redundant memory 10′, respectively. The defect location information obtainment circuit 50D writes the value “1” different from the initial value “0 to a memory cell corresponding to the address ADR (row+column address RCA), in the redundant memory 30-1 or 30-2 where the comparison result is produced, in the selected bit.

Thereby, if the comparison result from the memory BIST circuit 40-1 is a mismatch (if a defect arises in the redundant memory 30-1), the defect location information obtainment circuit 50D relates the comparison result to defect location information in the redundant memory 30-1 where the comparison result is produced, and writes it to the 1^{st} bit in the non-redundant memory 10′.

Similarly, if the comparison result from the memory BIST circuit 40-2 is a mismatch (if a defect arises in the redundant memory 30-2), the defect location information obtainment circuit 50D relates the comparison result to defect location information in the redundant memory 30-2 where the comparison result is produced, and writes it to the 0^{th} bit in the non-redundant memory 10′.

As depicted in FIG. 10, the defect location information obtainment circuit 50D in the fourth embodiment functioning as described above includes AND gates 51-1 and 51-2, an inverter element 56′, and selectors 57a and 57b, in addition to an FF 52, and selectors 53a, 53b, 53c, 54a, and 54b similar to those in the first and third embodiments.

The AND gates 51-1 and 51-2 are provided corresponding to the memory BIST circuits 40-1 and 40-2, respectively, and function in the manner similar to the AND gate 51 in the first embodiment. More specifically, the AND gate 51-1 outputs a logical AND between the comparison result CMP from the compare circuit 42 in the memory BIST circuit 40-1 and the store instruction SEN from the test signal generation circuit 41 in that memory BIST circuit 40-1. Similarly, the AND gate 51-2 outputs a logical AND between the comparison result CMP from the compare circuit 42 in the memory BIST circuit 40-2 and the store instruction SEN from the test signal generation circuit 41 in that memory BIST circuit 40-2.

The selectors 57a and 57b select one of the respective two inputs, in accordance with an examined redundant memory selection signal MSEL from the LSI tester 200 connected to the LSI 1D during a test. The examined redundant memory selection signal MSEL assumes a value “0” for testing the redundant memory 30-1, and assumes a value “1” for testing the redundant memory 30-2.

The selector 57a selects the address information RCA from the memory BIST circuit 40-1 and outputs it to the FF 52, when the selection signal MSEL is “0”. In contrast, the selector 57a selects the address information RCA from the memory BIST circuit 40-2 and outputs it to the FF 52, when the selection signal MSEL is “1”.

The selector 57b selects the output from the AND gate 51-1 and outputs it to the selectors 54b, 53c, and 53d, when the selection signal MSEL is “0”. In contrast, the selector 57b selects the output from the AND gate 51-2 and outputs it to the selectors 54b, 53c, and 53d, when the selection signal MSEL is “1”.

The inverter element 56′ inverts the value of the examined redundant memory selection signal MSEL from the LSI tester 200, and outputs the inversion to the non-redundant memory 10′, as a data mask signal DM[0]. Further, in the present embodiment, the value of the examined redundant memory selection signal MSEL from the LSI tester 200 is output to the non-redundant memory 10′, as the data mask signal DM[1].

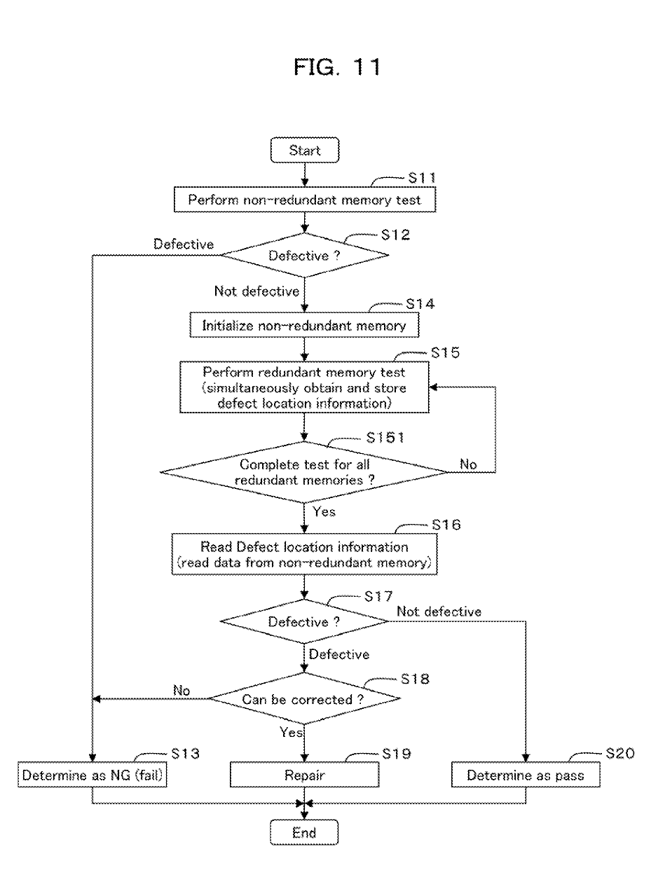

Next, a memory test procedure by the LSI 1D depicted in FIGS. 9 to 10 will be described with reference to the flowchart depicted in FIG. 11 (Steps S11 to S20, and S151).

The processing in Steps S11 to S14 and Steps S16 to S20 is performed in the LSI 1D in the fourth embodiment in the manner similar to the first embodiment, and detailed description thereof will be omitted.

While one pair of a redundant memory 30 and a memory BIST 40 is provided in the first embodiment, while two pairs of a redundant memory 30 and a memory BIST 40 are provided in the fourth embodiment. Accordingly, the processing in Step S15 (defect evaluation tests for the respective redundant memories 30-1 and 30-2) is repeated for the number of the pairs of a redundant memory 30 and a memory BIST 40, in the fourth embodiment.

More specifically, as depicted in FIG. 11, in the fourth embodiment, after a defect evaluation test for one redundant memory 30 is performed (Step S15), it is determined whether the processing has been completed for all of the redundant memories 30 (Step S151). If the processing has been completed for not all of the redundant memories 30 (the NO route from Step S151), the flow returns to the processing in Step S15 and processing similar to the above process is performed for unprocessed redundant memories 30. If the processing has been completed for all of the redundant memories 30 (the YES route from Step S151), the flow transitions to the processing in Step S16.

As described above, in Step S15, the defect evaluation tests for the respective redundant memories 30-1 and 30-2 are performed as follows. Here, after a defect evaluation test for the redundant memory 30-1 (defect location information obtainment) is completed, a defect evaluation test for the redundant memory 30-2 (defect location information obtainment) is performed.

Upon the defect evaluation test for the redundant memory 30-1, the instruction signals FGM and FRM from the LSI tester 200 are both set to “1”, and the selection signal MSEL is set to “0” for testing the redundant memory 30-1.

In response, the selector 57a selects the address information RCA from the memory BIST circuit 40-1 and outputs it to the FF 52, and the selector 57b selects the output from the AND gate 51-1 and outputs it to the selectors 54b, 53c, and 53d. Further, the data mask signal DM[0] with a value “1” and DM[1] with a value “0” are input to the non-redundant memory 10′, thereby writing of write data WD[0] to the 0^{th} bit is prohibited in the non-redundant memory 10′, while permitting writing of write data WD[1] to the 1^{st} bit.

When the defect evaluation test for the redundant memory 30-1 is performed by the memory BIST circuit 40-1, defect location information of the redundant memory 30-1 is obtained in the 1^{st} bit in the non-redundant memory 10′.

Further, upon the defect evaluation test for the redundant memory 30-2, the instruction signals FGM and FRM from the LSI tester 200 are both set to “1”, and the selection signal MSEL is set to “0” for testing the redundant memory 30-2.

In response, the selector 57a selects the address information RCA from the memory BIST circuit 40-2 and outputs it to the FF 52, and the selector 57b selects the output from the AND gate 51-2 and outputs it to the selectors 54b, 53c, and 53d. Further, the data mask signal DM[0] with a value “0” and DM[1] with a value “1” are input to the non-redundant memory 10′, thereby writing of write data WD[1] to the 1^{st} bit is prohibited in the non-redundant memory 10′, while permitting writing of write data WD[0] to the 0^{th} bit.

When the defect evaluation test for the redundant memory 30-2 is performed by the memory BIST circuit 40-2, defect location information of the redundant memory 30-2 is obtained in the 0^{th} bit in the non-redundant memory 10′.

Although the example wherein two pairs of a redundant memory 30 and a memory BIST circuit 40 are provided is described, the present disclosure is not limited to this. If n (n is a natural number of 3 or greater) pairs of a redundant memory 30 and a memory BIST circuit 40 are provided, defect location information of the n redundant memories 30 can be obtained to the 0^{th} to (n−1)^{th} bits in the non-redundant memory 10′, respectively, by enhancing the defect location information obtainment circuit 50D depicted in FIG. 10.

The LSI 1D including the testing apparatus of the above-described fourth embodiment provides advantages and effects similar to those in the first embodiment.

Further, in accordance with the LSI 1D including the testing apparatus in the fourth embodiment, even when there are multiple redundant memories 30 to be tested, defect location information in the multiple redundant memories 30 can be stored in a single data-masking non-redundant memory 10′.

### (4-5) Fifth Embodiment

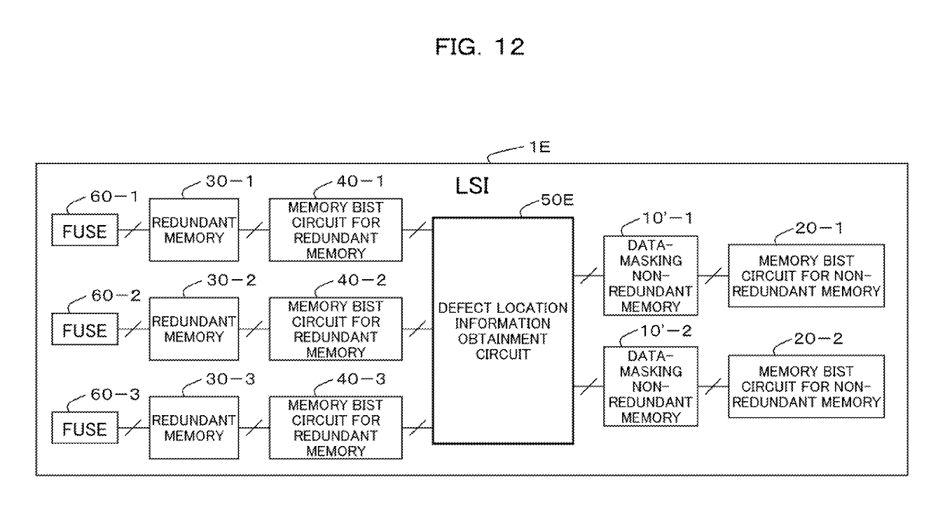

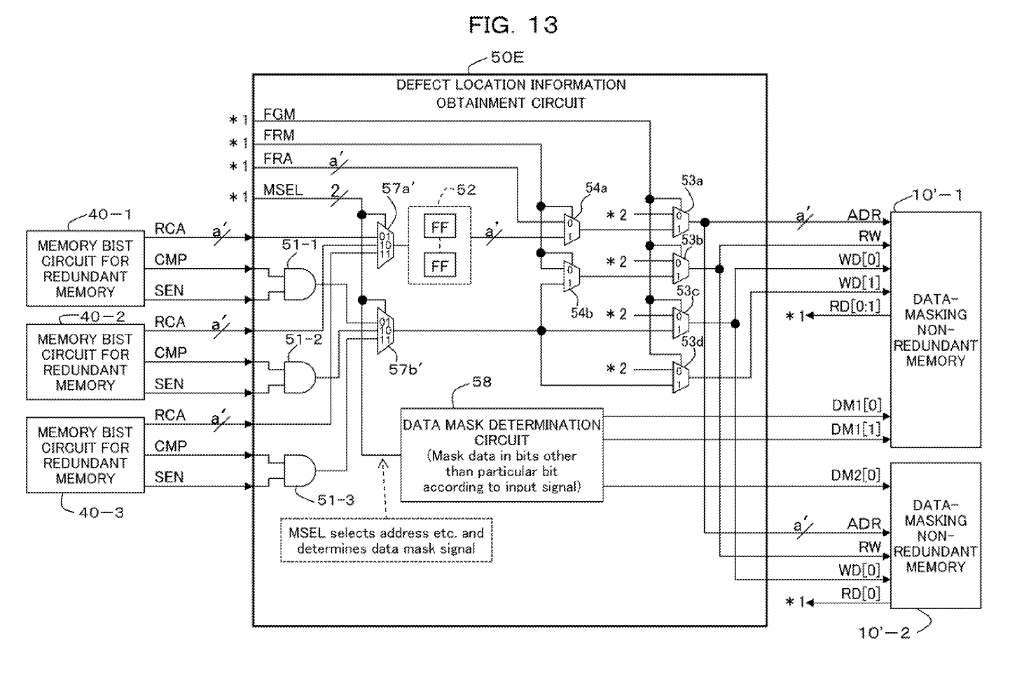

Now, referring to FIGS. 12 and 13, a configuration of an LSI 1E as an integrated circuit including a testing apparatus in a fifth embodiment will be described. FIG. 12 is a block diagram illustrating a configuration of an LSI 1E including a testing apparatus in the fifth embodiment, and FIG. 13 is a block diagram illustrating a detailed configuration of defect location information obtainment circuit 50E in the LSI 1E depicted in FIG. 12. Note that descriptions of the elements having the same reference symbols in the drawings as the elements described previously will be emitted since they refer to the same or substantially the same elements set forth previously.

As depicted in FIG. 12, the LSI 1E in fifth embodiment includes the two data-masking non-redundant memories 10′-1 and 10′-2, and three redundant memories 30-1, 30-2, and 30-3. The two data-masking non-redundant memories 10-1′ and 10-2′ are both configured similarly to the data-masking non-redundant memory 10′ in the third embodiment. The three redundant memories 30-1, 30-2, and 30-3 are all configured similarly to the redundant memory 30 in the first embodiment.

Further, the LSI 1E in fifth embodiment also includes memory BIST circuit 20-1 for the non-redundant memory 10′-1, a memory BIST circuit 20-2 for non-redundant memory 10′-2, a memory BIST circuit 40-1 for the redundant memory 30-1, a memory BIST circuit 40-2 for the redundant memory 30-2, a memory BIST circuit 40-3 for the redundant memory 30-3, and FUSEs (repair units) 60-1 to 60-3 corresponding to the three redundant memories 30-1 to 30-3, respectively. The two memory BIST circuits 20-1 and 20-2 are both configured similarly to the memory BIST circuit 20 in the first embodiment. The three memory BIST circuits 40-1 to 40-3 are both configured similarly to the memory BIST circuit 40 in the first embodiment. The three FUSEs 60-1 to 60-3 are both configured similarly to the FUSE 60 in the first embodiment.

In a defect location information obtainment circuit (write controller) 50E, the three redundant memories 30-1 to 30-3 (the memory BIST circuit 40-1 to 40-3) and the respective bits in the two non-redundant memories 10′-1 and 10′-2 are related to each other, in advance, by data mask determination circuit 58, which will be described later. For example, in the fifth embodiment, the 0^{th} bit in the non-redundant memory 10′-1 is related to the redundant memory 30-1 (the memory BIST circuit 40-1), the 1^{st} bit in the non-redundant memory 10′-1 is related to the redundant memory 30-2 (the memory BIST circuit 40-2), and the 0^{th} bit in the non-redundant memory 10′-2 is related to the redundant memory 30-3 (the memory BIST circuit 40-3).

If a result from a compare circuit 42 in one of the three memory BIST circuits 40-1 to 40-3 indicates a mismatch, the defect location information obtainment circuit 50E selects the bit in the non-redundant memory 10′-1 or 10′-2, related to the one of the three memory BIST circuits 40-1 to 40-3. The selection of the bit (the 0^{th} or 1^{st} bit) in the non-redundant memory 10′-1 or 10′-2 is made using the above-described data mask function and a data mask determination circuit 58 which will be described later. The defect location information obtainment circuit 50E writes the value “1” different from the initial value “0 to a memory cell corresponding to the address ADR (row+column address RCA), in the redundant memory 30-1 or 30-2 where the comparison result is produced, in the selected bit.

Thereby, if the comparison result from the memory BIST circuit 40-1 is a mismatch (if a defect arises in the redundant memory 30-1), the defect location information obtainment circuit 50E relates the comparison result to defect location information in the redundant memory 30-1 where the comparison result is produced, and writes it to the 0^{th} bit in the non-redundant memory 10′-1.

Further, if the comparison result from the memory BIST circuit 40-2 is a mismatch (if a defect arises in the redundant memory 30-2), the defect location information obtainment circuit 50E relates the comparison result to defect location information in the redundant memory 30-2 where the comparison result is produced, and writes it to the 1^{st} bit in the non-redundant memory 10′-1.

Still further, if the comparison result from the memory BIST circuit 40-3 is a mismatch (if a defect arises in the redundant memory 30-3), the defect location information obtainment circuit 50E relates the comparison result to defect location information in the redundant memory 30-3 where the comparison result is produced, and writes it to the 0^{th} bit in the non-redundant memory 10′-2.

As depicted in FIG. 13, the defect location information obtainment circuit 50E in the fifth embodiment functioning as described above includes AND gates 51-1 to 51-3, selectors 57a′ and 57b′, and a data mask determination circuit 58, in addition to an FF 52, and selectors 53a, 53b, 53c, 54a, and 54b similar to those in the fourth embodiment.

The AND gates 51-1 to 51-3 are provided corresponding to the memory BIST circuits 40-1 to 40-3, respectively, and function in the manner similar to the AND gate 51 in the first embodiment. More specifically, the AND gates 51-1 to 51-3 output a logical AND between a comparison result CMP from a compare circuit 42 in the memory BIST circuits 40-1 to 40-3 the store instruction SEN from a test signal generation circuit 41 in that memory BIST circuits 40-1 to 40-3, respectively.

The selectors 57a′ and 57b′ select one of the respective three inputs, in accordance with an examined redundant memory selection signal MSEL (2 bits) from the LSI tester 200 connected to the LSI 1E during a test. The examined redundant memory selection signal MSEL assumes a value “01” for testing the redundant memory 30-1, assumes a value “10” for testing the redundant memory 30-2, and assumes a value “11” for testing the redundant memory 30-3.

The selector 57a′ selects the address information RCA from the memory BIST circuit 40-1 and outputs it to the FF 52, when the selection signal MSEL is “01”. Further, the selector 57a′ selects the address information RCA from the memory BIST circuit 40-2 and outputs it to the FF 52, when the selection signal MSEL is “10”. Further, the selector 57a′ selects the address information RCA from the memory BIST circuit 40-3 and outputs it to the FF 52, when the selection signal MSEL is “11”.

The selector 57b′ selects the output from the AND gate 51-1 and outputs it to the selectors 54b, 53c, and 53d, when the selection signal MSEL is “01”. Further, the selector 57b′ selects the output from the AND gate 51-2 and outputs it to the selectors 54b, 53c, and 53d, when the selection signal MSEL is “10”. Further, the selector 57b′ selects the output from the AND gate 51-2 and outputs it to the selectors 54b, 53c, and 53d, when the selection signal MSEL is “11”.

Further, the selector 53a selects address information from the selector 54a, which will be later, and outputs it to the non-redundant memories 10′-1 and 10′-2 as the address ADR, when instruction signal FGM is “1”. The selector 53b selects a read/write instruction from the selector 54b, and outputs it to the non-redundant memories 10′-1 and 10′-2 as the read/write instruction RW, when instruction signal FGM is “1”. The selector 53c selects the output from the selector 57b′, and outputs it to the 0^{th} bit in the non-redundant memory 10′-1 and the 0^{th} bit in the non-redundant memory 10′-2, as data WD[0], when the instruction signal FGM is “1”. The selector 53d selects the output from the selector 57b′, and outputs it to the 1^{st} bit in the non-redundant memory 10′-1, as data WD[1], when the instruction signal FGM is “1”.

For masking bits other than the particular bit in accordance with the examined redundant memory selection signal MSEL (2 bits) from the LSI tester 200, the data mask determination circuit 58 outputs a data mask signal DM1[0] and a data mask signal DM1[1] for the non-redundant memory 10′-1, and a data mask signal DM2[0] for the non-redundant memory 10′-2. Specifically, the data mask determination circuit 58 in the present embodiment outputs the data mask signals DM1[0] with a value “0”, DM1[1] with a value “1”, and DM2[0] with a value “1”, for masking bits in the non-redundant memory 10′-1 other than the 0^{th} bit, when the selection signal MSEL is “01”. Further, the data mask determination circuit 58 outputs the data mask signals DM1[0] with a value “1”, DM1[1] with a value “0”, and DM2[0] with a value “1”, for masking bits in the non-redundant memory 10′-1 other than the 1^{st} bit, when the selection signal MSEL is “10”. Further, the data mask determination circuit 58 outputs the data mask signals DM1[0] with a value“1”, DM1[1] with a value “1”, and DM2[0] with a value “0”, for masking bits in the non-redundant memory 10′-2 other than the 0^{th} bit, when the selection signal MSEL is “11”.

A memory test of the LSI 1E in the fifth embodiment configured as described above is performed according to the flowchart depicted in FIG. 11 (Steps S11 to S20, and S151), in a manner similar to that in fourth embodiment.

In the LSI 1E in the fifth embodiment, however, in Step S15, defect evaluation tests for the respective redundant memories 30-1 to 30-3 are performed as follows. Here, defect evaluation tests (defect location information obtainment) are performed for the redundant memories 30-1, 30-2, and 30-3, in this order.

Upon the defect evaluation test for the redundant memory 30-1, the instruction signals FGM and FRM from the LSI tester 200 are both set to “1”, and the selection signal MSEL is set to “01” for testing the redundant memory 30-1.

In response, the selector 57a′ selects the address information RCA from the memory BIST circuit 40-1 and outputs it to the FF 52, and the selector 57b′ selects the output from the AND gate 51-1 and outputs it to the selectors 54b, 53c, and 53d. Further, the data mask determination circuit 58 outputs the data mask signals DM1[0] with a value “0”, DM1[1] with a value “1”, and DM2[0] with a value “1” for masking bits in the non-redundant memory 10′-1 other than the 0^{th} bit, thereby permitting writing of write data WD[0] to the 0^{th} bit in the non-redundant memory 10′-1. When the defect evaluation test for the redundant memory 30-1 is performed by the memory BIST circuit 40-1, defect location information of the redundant memory 30-1 is obtained in the 0^{th} bit in the non-redundant memory 10′-1.

Further, upon the defect evaluation test for the redundant memory 30-2, the instruction signals FGM and FRM from the LSI tester 200 are both set to “1”, and the selection signal MSEL is set to “10” for testing the redundant memory 30-2.

In response, the selector 57a′ selects the address information RCA from the memory BIST circuit 40-2 and outputs it to the FF 52, and the selector 57b′ selects the output from the AND gate 51-2 and outputs it to the selectors 54b, 53c, and 53d. Further, the data mask determination circuit 58 outputs the data mask signals DM1[0] with a value “1”, DM1[1] with a value “0”, and DM2[0] with a value “1” for masking bits in the non-redundant memory 10′-1 other than the 1^{st} bit, thereby permitting writing of write data WD[1] to the 1^{st} bit in the non-redundant memory 10′-1. When the defect evaluation test for the redundant memory 30-2 is performed by the memory BIST circuit 40-2, defect location information of the redundant memory 30-2 is obtained in the 1^{st} bit in the non-redundant memory 10′-1.

Further, upon the defect evaluation test for the redundant memory 30-3, the instruction signals FGM and FRM from the LSI tester 200 are both set to “1”, and the selection signal MSEL is set to “11” for testing the redundant memory 30-3.

In response, the selector 57a′ selects the address information RCA from the memory BIST circuit 40-3 and outputs it to the FF 52, and the selector 57b′ selects the output from the AND gate 51-3 and outputs it to the selectors 54b, 53c, and 53d. Further, the data mask determination circuit 58 outputs the data mask signals DM1[0] with a value “1”, DM1[1] with a value “1”, and DM2[0] with a value “0” for masking bits in the non-redundant memory 10′-2 other than the 0^{th} bit, thereby permitting writing of write data WD[0] to the 0^{th} bit in the non-redundant memory 10′-2. When the defect evaluation test for the redundant memory 30-3 is performed by the memory BIST circuit 40-3, defect location information of the redundant memory 30-3 is obtained in the 0^{th} bit in the non-redundant memory 10′-2.

The LSI 1E including the testing apparatus of the above-described fifth embodiment provides advantages and effects similar to those in the first embodiment.

Further, in accordance with the LSI 1E including the testing apparatus in the fifth embodiment, even when there are multiple redundant memories 30 to be tested, defect location information in the multiple redundant memories 30 can be stored in the respective bits in multiple redundant memories 10′. Accordingly, the number of redundant memories 30 greater than the bit count in a non-redundant memory 10′ can be handled, which enables reliable obtainment of a defect occurrence location in the respective redundant memories 30.

### (4-6) Sixth Embodiment

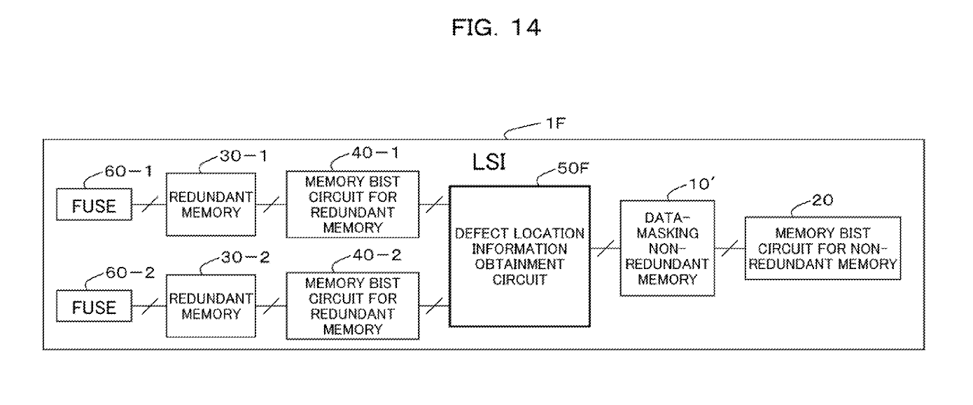

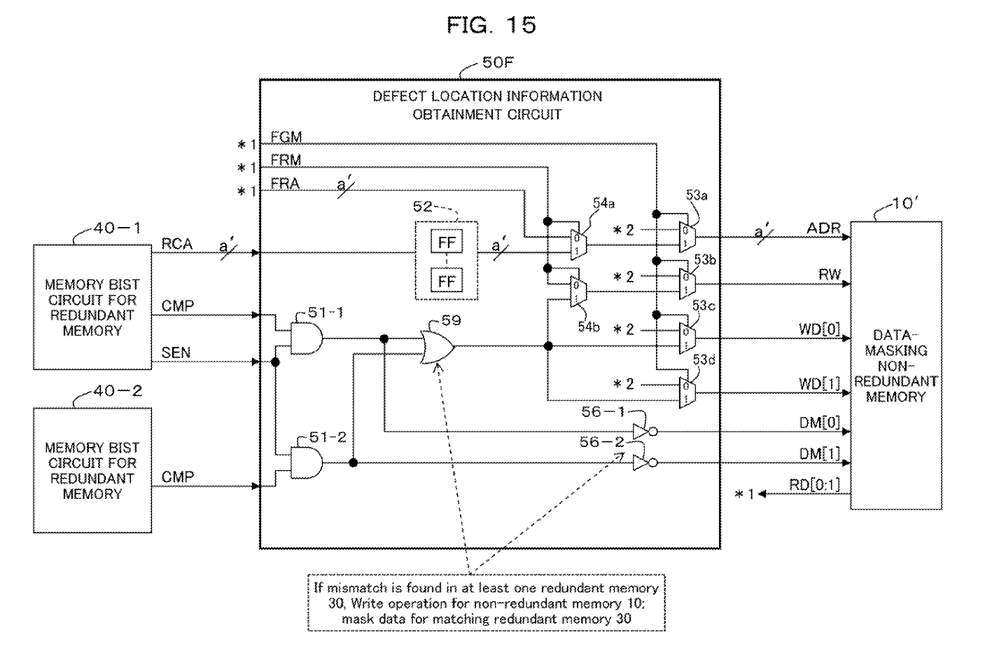

Now, referring to FIGS. 14 and 15, a configuration of an LSI 1F as an integrated circuit including a testing apparatus in a sixth embodiment will be described. FIG. 14 is a block diagram illustrating a configuration of an LSI 1F including a testing apparatus in the sixth embodiment, and FIG. 15 is a block diagram illustrating a detailed configuration of defect location information obtainment circuit 50F in the LSI 1F depicted in FIG. 14. Note that descriptions of the elements having the same reference symbols in the drawings as the elements described previously will be emitted since they refer to the same or substantially the same elements set forth previously.

As depicted in FIG. 14, the LSI 1F in the sixth embodiment includes a defect location information obtainment circuit 50F, in addition to a data-masking non-redundant memory 10′, a memory BIST circuit 20, two redundant memories 30-1 and 30-2, two memory BIST circuits 40-1 and 40-2, and the FUSEs 60-1 and 60-2 similar to those in the fourth embodiment.

Particularly, the LSI 1F in the sixth embodiment is adapted to obtain defect location information of multiple (two in the embodiment) redundant memories 30 simultaneously, as will be described later. Hence, in the sixth embodiment, the address count of an address RCA of the redundant memory 30-1 equals the address count of an address RCA of the redundant memory 30-2. Further, in the sixth embodiment, a memory test pattern (refer to FIG. 19, for example) for defect evaluation used to obtain defect location information of the redundant memory 30-1 is identical to a defect evaluation memory test pattern used to obtain defect location information of the redundant memory 30-2.

When these conditions are met, an address RCA and a store instruction SEN from the memory BIST circuit 40-1 is identical to an address RCA and a store instruction SEN from the memory BIST circuit 40-2. Therefore, as depicted in FIG. 15, in the present embodiment, an address RCA and a store instruction SEN from the memory BIST circuit 40-1 are used for illustration.

The defect location information obtainment circuit (write controller) 50F selects two bits (the 0^{th} and 1^{st} bits) in the non-redundant memory 10′, which are related to the two memory BIST circuits 40-1 and 40-2 in advance, if a comparison result from a compare circuit 42 in the two memory BIST circuits 40-1 and 40-2 is a mismatch. The selection between the 0^{th} or 1^{st} bit in the non-redundant memory 10′ is made using the data mask function described above. In the present embodiment, the memory BIST circuits 40-1 and 40-2 are related to the 0^{th} bit and the 1^{st} bit in the non-redundant memory 10′, respectively. The defect location information obtainment circuit 50F writes the value “1” different from the initial value “0 to memory cells corresponding to the address RCA in the redundant memories 30-1 and 30-2 where the comparison result is produced, in the selected two bits.

Thereby, if the comparison result from the memory BIST circuit 40-1 is a mismatch (if a defect arises in the redundant memory 30-1), the defect location information obtainment circuit 50F relates the comparison result to defect location information in the redundant memory 30-1 where the comparison result is produced, and writes it to the 0^{th} bit in the non-redundant memory 10′. Similarly, if the comparison result from the memory BIST circuit 40-2 is a mismatch (if a defect arises in the redundant memory 30-2), the defect location information obtainment circuit 50F relates the comparison result to defect location information in the redundant memory 30-2 where the comparison result is produced, and writes it to the 1^{st} bit in the non-redundant memory 10′ simultaneously.

As depicted in FIG. 15, the defect location information obtainment circuit 50F in the sixth embodiment functioning as described above includes inverter elements 56-1 and 56-2 and an OR gate 59, in addition to the FF 52, the selectors 53a, 53b, 53c, 53d, 54a and 54b, and the AND gates 51-1 and 51-2 similar to those in the fourth embodiment.

The AND gates 51-1 and 51-2 are provided corresponding to the memory BIST circuits 40-1 and 40-2, respectively. In the sixth embodiment, the AND gate 51-1 outputs a logical AND between the comparison result CMP from the compare circuit 42 in the memory BIST circuit 40-1 and the store instruction SEN from the test signal generation circuit 41 in that memory BIST circuit 40-1. Further, the AND gate 51-2 outputs a logical AND between the comparison result CMP from the compare circuit 42 in the memory BIST circuit 40-2 and the store instruction SEN from the test signal generation circuit 41 in that memory BIST circuit 40-1.

The OR gate 59 outputs a logical OR between the output from the AND gate 51-1 and the output from the AND gate 51-2, to the selectors 54b, 53c, and 53d.

The inverter element 56′ inverts the output from the AND gate 51-1, and outputs the inversion to the non-redundant memory 10′, as a data mask signal DM[0].

The inverter element 56′ inverts the output from the AND gate 51-2, and outputs the inversion to the non-redundant memory 10′, as a data mask signal DM[1].

A memory test of the LSI 1F in the sixth embodiment configured as described above is performed according to the flowchart depicted in FIG. 4 (Steps S11 to S20), in a manner similar to that in the first embodiment.

In the LSI 1F in the sixth embodiment, however, in Step S15, defect evaluation tests (defect location information obtainment) for the two redundant memories 30-1 and 30-2 are performed simultaneously.

During the test, when a defect arises in at least one of the two redundant memories 30-1 and 30-2, in response to at least one of the outputs from the two AND gates 51-1 and 51-2 changing to “1”, the output from the OR gate 59 changes to “1”. In response, a write instruction RW with a value of “1” is output to the non-redundant memory 10′, and “1” is output, as write data WD[0] and WD[1] to be written to the 0^{th} and 1^{st} bits in the non-redundant memory 10′.

If the outputs from the two AND gates 51-1 and 51-2 are both “1”, the data mask signals DM[0] and DM[1] are both set to “0” by the inverter elements 56-1 and 56-2. This permits writing of write data WD[0] and WD[1] to the 0^{th} and 1^{st} bits in the non-redundant memory 10′, respectively. Therefore, “1” is simultaneously written to memory cells corresponding to the address indicating the defect location, in both the 0^{th} and 1^{st} bits in the non-redundant memory 10′, and defect location information in the redundant memories 30-1 and 30-2 is obtained.

Further, if the output from the AND gate 51-1 is “1” and the output from the AND gate 51-2 is “0”, the data mask signals DM[0] and DM[1] are set to “0” and “1” by the inverter elements 56-1 and 56-2, respectively. Thereby, in the non-redundant memory 10′, writing of write data WD[0] to the 0^{th} bit is permitted, while prohibiting writing of write data WD[1] to the 1^{st} bit by masking the 1^{st} bit. Accordingly, “1” is written to a memory cell corresponding to the address indicating the defect location, only in the 0^{th} bit in the non-redundant memory 10′.

Similarly, if the output from the AND gate 51-1 is “0” and the output from the AND gate 51-2 is “1”, the data mask signals DM[0] and DM[1] are set to “1” and “01” by the inverter elements 56-1 and 56-2, respectively. Thereby, in the non-redundant memory 10′, writing of write data WD[0] to the 0^{th} bit is prohibited by masking the 0^{th} bit, while permitting writing of write data WD[1] to the 1^{st} bit. Accordingly, “1” is written to a memory cell corresponding to the address indicating the defect location, only in the 1^{st} bit in the non-redundant memory 10′.

Note that, if the outputs from the two AND gates 51-1 and 51-2 are both “0”, the data mask signals DM[0] and DM[1] are both set to “1” by the inverter elements 56-1 and 56-2. Thereby, writing of the write data WD[0] and WD[1] to the 0^{th} and 1^{st} bits in the non-redundant memory 10′ is prohibited. Accordingly, overwriting to both the 0^{th} and 1^{st} bits in the non-redundant memory 10′ is avoided.

The LSI 1F including the testing apparatus of the above-described sixth embodiment provides advantages and effects similar to those in the first embodiment.

Further, in accordance with the LSI 1F including the testing apparatus in the sixth embodiment, when there are multiple redundant memories 30 to be tested, tests for the multiple redundant memories 30 are performed simultaneously, and defect location information in the multiple redundant memories 30 can be obtained and stored simultaneously in the respective bits in one of multiple non-redundant memories 10′. Accordingly, the number of redundant memories 30 greater than the bit count in a non-redundant memory 10′ can be handled, which enables reliable obtainment of a defect occurrence location in the respective redundant memories 30. Further, defect occurrence locations in multiple redundant memories 30 can be obtained in a shorter time.

Although the example wherein two pairs of a redundant memory 30 and a memory BIST circuit 40 are provided is described in the sixth embodiment, the present disclosure is not limited to this. If n (n is a natural number of 3 or greater) pairs of a redundant memory 30 and a memory BIST circuit 40 are provided, defect location information of the n redundant memories 30 can be obtained simultaneously to the 0^{th} to (n−1)^{th} bits in the non-redundant memory 10′, respectively, by enhancing the defect location information obtainment circuit 50F depicted in FIG. 15.

### (5) OTHERS

While preferred embodiments of the invention have been described in detailed above, it should be understood that these are exemplary of the invention and are not to be considered as limiting. Any modifications and variations can be made without departing from the sprit of the invention.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments) of the present invention have been described in detail, it should be understood that the various changes, substitutions, and alterations could be made hereto without departing from the spirit and scope of the invention.

What is claimed is:

1. An integrated circuit comprising:
a redundant memory comprising a spare memory cell;
a first generator that generates a first test pattern to be provided to the redundant memory, and an expected value of data expected to be output from the redundant memory, in response to the first test pattern being supplied to the redundant memory;
a first comparator that compares the expected value generated by the first generator, against data output from the redundant memory in response to the first test pattern generated by the first generator being supplied to the redundant memory;
at least one storage that stores a result of the comparison by the first comparator; and
a write controller that writes the comparison result to the at least one storage while relating the comparison result to location information in the redundant memory where the comparison result is produced, if the comparison result by the first comparator indicates a mismatch, while suppressing the comparison result from being written to the at least one storage, if the comparison result by the first comparator indicates a match.

2. The integrated circuit according to claim 1, further comprising:
an initializer that writes an initial value to respective memory cells in the at least one storage before writing the comparison result to the at least one storage,
wherein the write controller, if the comparison result by the first comparator indicates a mismatch, writes the comparison result to the at least one storage while relating the comparison result to the location information in the redundant memory where the comparison result is produced, by writing a value different from the initial value, as the comparison result, in a location in the at least one storage corresponding to a location in the redundant memory where the comparison result is produced.

3. The integrated circuit according to claim 2, wherein the write controller, if a result of a comparison by the first comparator, between the expected value and data that is specified by an address included in the first test pattern in the at least one storage and is read from the redundant memory indicates a mismatch, writes a value different from the initial value to a memory cell corresponding to the address in a certain bit in the at least one storage.

4. The integrated circuit according to claim 2, wherein the at least one storage comprises a plurality of storages, and
the write controller, if a result of a comparison by the first comparator, between the expected value and data that is specified by an address included in the first test pattern and is read from the redundant memory indicates a mismatch, selects one of the plurality of storages according to the address and writes a value different from the initial value to a memory cell corresponding to the address in a certain bit in the selected storage.

5. The integrated circuit according to claim 2, wherein the write controller, if a result of a comparison by the first comparator, between the expected value and data that is specified by an address included in the first test pattern and is read from the redundant memory indicates a mismatch, selects a bit in the at least one storage according to the address and writes a value different from the initial value to a memory cell corresponding to the address in the selected bit.

6. The integrated circuit according to claim 2, further comprising:
a plurality of sets of the redundant memory, the first generator, and the first comparator,
wherein the write controller, in one of the plurality of sets, if a result of a comparison by the first comparator, between the expected value and data that is specified by an address included in the first test pattern and is read from the redundant memory indicates a mismatch, selects a bit in the storage related to the one of the plurality of sets in advance, and writes a value different from the initial value to a memory cell corresponding to the address in the selected bit.

7. The integrated circuit according to claim 2, further comprising:
a plurality of sets of the redundant memory, the first generator, and the first comparator,
wherein the at least one storage comprises a plurality of storages,
the write controller relates one of the plurality of sets to one bit in the plurality of storages, in advance, and
the write controller, in one of the plurality of sets, if a result of a comparison by the first comparator, between the expected value and data that is specified by an address included in the first test pattern and is read from the redundant memory indicates a mismatch, selects a bit in one of the plurality of storages related to the one of the plurality of sets in advance, and writes a value different from the initial value to memory cells corresponding to the address in the selected bit.

8. The integrated circuit according to claim 2, further comprising:
a plurality of sets of the redundant memory, the first generator, and the first comparator,
wherein the write controller, in at least two of the plurality of sets, if a result of a comparison by the first comparator, between the expected value and data that is specified by an address included in the first test pattern and is read from the redundant memory indicates a mismatch, selects at least two bits in the storage related to the two of the plurality of sets in advance, and simultaneously writes a value different from the initial value to memory cells corresponding to the address in the two selected bits.

9. The integrated circuit according to claim 5, wherein the at least one storage includes a data mask function to permit writing of a particular bit in a plurality of bits, and the write controller selects a bit for writing the value different from the initial value using the data mask function of the at least one storage.

10. The integrated circuit according to claim 1, further comprising a repair unit that replaces a memory cell in a failed location identified based on the comparison result and the location information stored in the at least one storage, with the spare memory cell.

11. The integrated circuit according to claim 1, further comprising a non-redundant memory without a spare memory cell, wherein the non-redundant memory is used as the at least one storage.

12. The integrated circuit according to claim 11, further comprising:
a second generator that generates a second test pattern to be provided to the non-redundant memory, and an expected value of data expected to be output from the non-redundant memory, in response to the second test pattern being supplied to the non-redundant memory; and
a second comparator that compares the expected value generated by the second generator, against data output from the non-redundant memory in response to the second test pattern generated by the second generator being supplied to the non-redundant memory;
wherein a non-redundant memory where a comparison result by the second comparator does not indicate a mismatch is used as the at least one storage.

13. A testing apparatus provided in an integrated circuit and testing memories in the integrated circuit, the testing apparatus comprising:
a first generator that generates a first test pattern to be provided to a redundant memory comprising a spare memory cell in the integrated circuit, and an expected value of data expected to be output from the redundant memory, in response to the first test pattern being supplied to the redundant memory;
a first comparator that compares the expected value generated by the first generator, against data output from the redundant memory in response to the first test pattern generated by the first generator being supplied to the redundant memory;
at least one storage that stores a result of the comparison by the first comparator; and
a write controller that writes the comparison result to the at least one storage while relating the comparison result to location information in the redundant memory where the comparison result is produced, if the comparison result by the first comparator indicates a mismatch, while suppressing the comparison result from being written to the at least one storage, if the comparison result by the first comparator indicates a match.

14. The apparatus according to claim 13, further comprising:
an initializer that writes an initial value to respective memory cells in the at least one storage before writing the comparison result to the at least one storage,
wherein the write controller, if the comparison result by the first comparator indicates a mismatch, writes the comparison result to the at least one storage while relating the comparison result to the location information in the redundant memory where the comparison result is produced, by writing a value different from the initial value, as the comparison result, in a location in the at least one storage corresponding to a location in the redundant memory where the comparison result is produced.

15. The apparatus according to claim 14, wherein the write controller, if a result of a comparison by the first comparator, between the expected value and data that is specified by an address included in the first test pattern in the at least one storage and is read from the redundant memory indicates a mismatch, writes a value different from the initial value to a memory cell corresponding to the address in a certain bit in the at least one storage.

16. The apparatus according to claim 13, further comprising: a repair unit that replaces a memory cell in a failed location identified based on the comparison result and the location information stored in the at least one storage, with the spare memory cell.

17. The apparatus according to claim 13, wherein a non-redundant memory without a spare memory cell in the integrated circuit is used as the at least one storage.

18. The apparatus according to claim 17, further comprising:
a second generator that generates a second test pattern to be provided to the non-redundant memory, and an expected value of data expected to be output from the non-redundant memory, in response to the second test pattern being supplied to the non-redundant memory;
a second comparator that compares the expected value generated by the second generator, against data output from the non-redundant memory in response to the second test pattern generated by the second generator being supplied to the non-redundant memory;
wherein a non-redundant memory where a comparison result by the second comparator does not indicate a mismatch is used as the at least one storage.

19. A method of testing an integrated circuit comprising a redundant memory comprising a spare memory cell; a first generator that generates a first test pattern to be provided to the redundant memory, and an expected value of data expected to be output from the redundant memory, in response to the first test pattern being supplied to the redundant memory; a first comparator that compares the expected value generated by the first generator, against data output from the redundant memory in response to the first test pattern generated by the first generator being supplied to the redundant memory; a non-redundant memory without a spare memory cell; a second generator that generates a second test pattern to be provided to the non-redundant memory, and an expected value of data expected to be output from the non-redundant memory, in response to the second test pattern being supplied to the non-redundant memory; and a second comparator that compares the expected value generated by the second generator, against data output from the non-redundant memory in response to the second test pattern generated by the second generator being supplied to the non-redundant memory, the method comprising:
testing the non-redundant memory by the second generator and the second comparator;
initializing by writing an initial value to respective memory cells in the non-redundant memory, if a comparison result by the second comparator does not indicate a mismatch;
if the comparison result by the first comparator indicates a mismatch, writing the comparison result to the non-redundant memory while relating the comparison result to the location information in the redundant memory where the comparison result is produced, by writing a value different from the initial value, as the comparison result, in a location in the non-redundant memory corresponding to a location in the redundant memory where the comparison result is produced; and
suppressing the comparison result from being written to the non-redundant memory, if the comparison result by the first comparator indicates a match.
